(19) United States
(12) Patent Application Publication
(10) Pub. No.: US 2026/0163363 A1
(43) Pub. Date: Jun. 11, 2026

(54) ELECTROSTATIC PROTECTION CIRCUIT, RECEPTION CHIP, SIGNAL TRANSMITTER, AND ELECTRONIC APPARATUS

(71) Applicant: ROHM CO., LTD., Kyoto (JP)

(72) Inventor: Junichi SEKITO, Kyoto (JP)

(21) Appl. No.: 19/404,456

(22) Filed: Dec. 1, 2025

(30) Foreign Application Priority Data
Dec. 6, 2024 (JP) 2024-213356

(51) Int. Cl. H02H 9/02; H02H 9/00

(52) U.S. Cl. CPC H02H 9/02; H02H 9/005

(57) ABSTRACT

An electrostatic protection circuit includes: a first protection element configured with an anode connected to a first pad; a second protection element configured with a cathode connected to the first pad; a third protection element configured with a cathode connected to a cathode of the first protection element and an anode connected to a reference potential terminal; and a fourth protection element configured with an anode connected to an anode of the second protection element and a cathode connected to the reference potential terminal.

### CROSS-REFERENCE TO RELATED APPLICATION

The present invention claims priority under 35 U.S.C. § 119 to Japanese Patent Application No. 2024-213356, filed on Dec. 6, 2024, the entire contents of which are incorporated herein by reference.

### TECHNICAL FIELD

The present disclosure relates to an electrostatic protection circuit, a reception chip, a signal transmitter, and an electronic apparatus.

### BACKGROUND

In the related art, signal transmitters that transmit signals between a primary circuit system and a secondary circuit system while electrically insulating the primary circuit system and the secondary circuit system from each other have been used in a variety of applications.

### BRIEF DESCRIPTION OF DRAWINGS

The accompanying drawings, which are incorporated in and constitute a part of the specification, illustrate embodiments of the present disclosure.

FIG. 1 is a diagram showing a basic configuration of a signal transmitter.

FIG. 2 is a diagram showing a basic structure of a transformer chip.

FIG. 3 is a perspective view of a semiconductor device used as a two-channel transformer chip.

FIG. 4 is a plan view of the semiconductor device shown in FIG. 3.

FIG. 5 is a plan view showing a layer in which a low-potential coil is formed in the semiconductor device of FIG. 3.

FIG. 6 is a plan view showing a layer in which a high-potential coil is formed in the semiconductor device of FIG. 3.

FIG. 7 is a cross-sectional view taken along line VIII-VIII shown in FIG. 6.

FIG. 8 is a diagram showing enlargement (separation structure) of region XIII shown in FIG. 7.

FIG. 9 is a schematic diagram showing an example of a layout of a transformer chip.

FIG. 10 is a diagram showing a first embodiment of an insulation switch.

FIG. 11 is a diagram showing a signal transmission operation of the first embodiment.

FIG. 12 is a diagram showing a second embodiment of an insulation switch.

FIG. 13 is a diagram showing an example of a reception signal in the second embodiment.

FIG. 14 is a diagram showing a third embodiment of an insulation switch.

FIG. 15 is a diagram showing an example of a surge path in an electrostatic protection circuit.

FIG. 16 is a diagram showing an example of a reception signal in the third embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Signal Transmitter (basic Configuration)

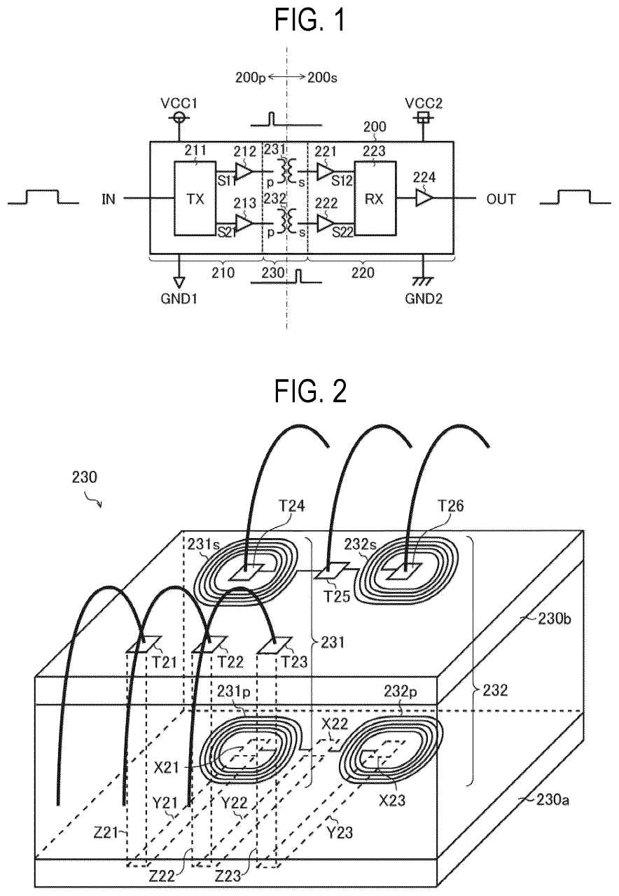

FIG. 1 is a diagram showing a basic configuration of a signal transmitter. A signal transmitter 200 in this configuration example is a semiconductor integrated circuit device (a so-called insulated gate driver IC) configured to insulate between a primary circuit system 200p (VCC1-GND1 system) and a secondary circuit system 200s (VCC2-GND2 system), transmit a pulse signal from the primary circuit system 200p to the secondary circuit system 200s, and drive a gate of a switch element (not shown) installed in the secondary circuit system 200s. For example, the signal transmitter 200 is formed by sealing a controller chip 210, a driver chip 220, and a transformer chip 230 in a single package.

The controller chip 210 is a semiconductor chip configured to operate by being supplied with a power supply voltage VCC1 (for example, a maximum of 7 V based on GND1). For example, a pulse transmission circuit 211 and buffers 212 and 213 are integrated in the controller chip 210.

The pulse transmission circuit 211 is a pulse generator configured to generate transmission pulse signals S11 and S21 in response to an input pulse signal IN. More specifically, when notifying that the input pulse signal IN is at a high level, the pulse transmission circuit 211 pulse-drives the transmission pulse signal S11 (outputs a single-shot or multiple-shot transmission pulse). When notifying that the input pulse signal IN is at a low level, the pulse transmission circuit 211 pulse-drives the transmission pulse signal S21. That is, the pulse transmission circuit 211 pulse-drives one of the transmission pulse signals S11 and S21 according to a logic level of the input pulse signal IN.

The buffer 212 receives an input of the transmission pulse signal S11 from the pulse transmission circuit 211 and pulse-drives the transformer chip 230 (specifically, a transformer 231).

The buffer 213 receives an input of the transmission pulse signal S21 from the pulse transmission circuit 211 and pulse-drives the transformer chip 230 (specifically, a transformer 232).

The driver chip 220 is a semiconductor chip configured to operate by being supplied with a power supply voltage VCC2 (for example, a maximum of 30 V based on GND 2). For example, buffers 221 and 222, a pulse reception circuit 223, and a driver 224 are integrated in the driver chip 220.

The buffer 221 waveform-shapes a reception pulse signal S12 induced in the transformer chip 230 (specifically, the transformer 231) and outputs the same to the pulse reception circuit 223.

The buffer 222 waveform-shapes a reception pulse signal S22 induced in the transformer chip 230 (specifically, the transformer 232) and outputs the same to the pulse reception circuit 223.

The pulse reception circuit 223 generates an output pulse signal OUT by driving the driver 224 in response to the reception pulse signals S12 and S22 input via the buffers 221 and 222. More specifically, the pulse reception circuit 223 drives the driver 224 so as to raise the output pulse signal OUT to a high level in response to the pulse drive of the reception pulse signal S12 and to lower the output pulse signal OUT to a low level in response to the pulse drive of the reception pulse signal S22. That is, the pulse reception circuit 223 switches a logic level of the output pulse signal OUT according to the logic level of the input pulse signal IN. As the pulse reception circuit 223, for example, an RS flip-flop may be used.

The driver 224 generates the output pulse signal OUT based on the drive control of the pulse reception circuit 223.

The transformer chip 230 uses the transformers 231 and 232 to provide DC insulation between the controller chip 210 and the driver chip 220, while outputting the transmission pulse signals S11 and S21 input from the pulse transmission circuit 211, as the reception pulse signals S12 and S22, respectively, to the pulse reception circuit 223. In the present disclosure, the phrase “DC insulation” means that an object to be insulated is not connected by a conductor.

More specifically, the transformer 231 outputs the reception pulse signal S12 from a secondary side coil 231s in response to the transmission pulse signal S11 input to a primary side coil 231p. On the other hand, the transformer 232 outputs the reception pulse signal S22 from a secondary side coil 232s in response to the transmission pulse signal S21 input to a primary side coil 232p.

Thus, due to characteristics of a spiral coil used for inter-insulation communication, the input pulse signal IN is separated into the two transmission pulse signals S11 and S21 (corresponding to a rise signal and a fall signal), and then transmitted from the primary circuit system 200p to the secondary circuit system 200s via the two transformers 231 and 232.

The signal transmitter 200 of this configuration example independently includes a transformer chip 230 on which only the transformers 231 and 232 are mounted, separately from the controller chip 210 and the driver chip 220, and is formed by sealing these three chips in a single package.

According to such a configuration, both the controller chip 210 and the driver chip 220 can be formed by a general low-to-medium withstand voltage process (withstand voltage of several V to several tens of V), which eliminates the need to use a dedicated high withstand voltage process (several kV withstand voltage), making it possible to reduce manufacturing costs.

The signal transmitter 200 can be suitably used, for example, in a power supply device or a motor drive device of in-vehicle equipment mounted in a vehicle. The above-described vehicle includes an electric vehicle (xEV such as BEV [battery electric vehicle], HEV [hybrid electric vehicle], PHEV/PHV [plug-in hybrid electric vehicle/plug-in hybrid vehicle], or FCEV/FCV [fuel cell electric vehicle/fuel cell vehicle]) in addition to an engine vehicle.

### Transformer Chip (Basic Structure)

Next, a basic structure of the transformer chip 230 will be described. FIG. 2 is a diagram showing a basic structure of the transformer chip 230. In the transformer chip 230 of this figure, the transformer 231 includes the primary side coil 231p and the secondary side coil 231s facing each other in a vertical direction. The transformer 232 includes the primary side coil 232p and the secondary side coil 232s facing each other in the vertical direction.

The primary side coils 231p and 232p are both formed on a first wiring layer (lower layer in this figure) 230a of the transformer chip 230. The secondary side coils 231s and 232s are both formed on a second wiring layer (upper layer in this figure) 230b of the transformer chip 230. The secondary side coil 231s is arranged directly above the primary side coil 231p and faces the primary side coil 231p. Further, the secondary side coil 232s is arranged directly above the primary side coil 232p and faces the primary side coil 232p.

The primary side coil 231p is spirally laid so as to surround a periphery of an internal terminal X21 in a clockwise direction, with a first end connected to the internal terminal X21 as a start point, and with a second end corresponding to an end point connected to an internal terminal X22. On the other hand, the primary side coil 232p is spirally laid so as to surround a periphery of an internal terminal X23 in a counter clockwise direction, with a first end connected to the internal terminal X23 as a start point, and with a second end corresponding to an end point connected to the internal terminal X22. The internal terminals X21, X22, and X23 are linearly arranged in the order shown.

The internal terminal X21 is connected to an external terminal T21 of a second layer 230b through a conductive wiring Y21 and a via Z21. The internal terminal X22 is connected to an external terminal T22 of the second layer 230b through a conductive wiring Y22 and a via Z22. The internal terminal X23 is connected to an external terminal T23 of the second layer 230b through a conductive wiring Y23 and a via Z23. The external terminals T21 to T23 are linearly arranged side by side and used for wire bonding with the controller chip 210.

The secondary side coil 231s is spirally laid so as to surround a periphery of an external terminal T24 in a counter clockwise direction, with a first end connected to the external terminal T24 as a start point, and with a second end corresponding to an end point connected to an external terminal T25. On the other hand, the secondary side coil 232s is spirally laid so as to surround a periphery of an external terminal T26 in a clockwise direction, with a first end connected to the external terminal T26 as a start point, and with a second end corresponding to an end point connected to the external terminal T25. The external terminals T24, T25, and T26 are linearly arranged side by side in the order shown in the figure and used for wire bonding with the driver chip 220.

The secondary side coils 231s and 232s are AC-connected to the primary side coils 231p and 232p by magnetic coupling, respectively, and are DC-insulated from the primary side coils 231p and 232p. That is, the driver chip 220 is AC-connected to the controller chip 210 via the transformer chip 230 and is DC-insulated from the controller chip 210 by the transformer chip 230.

### Transformer Chip (2-Channel Type)

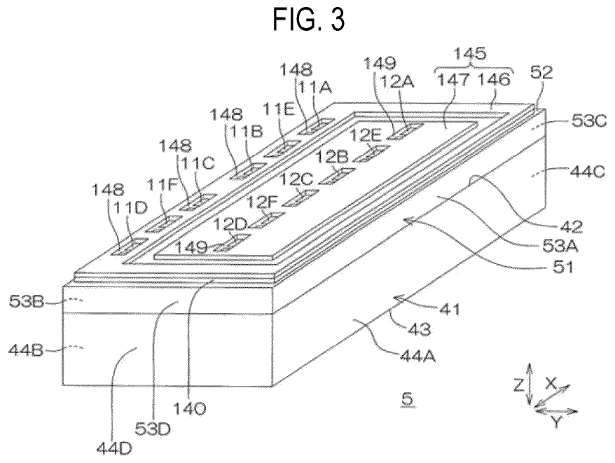

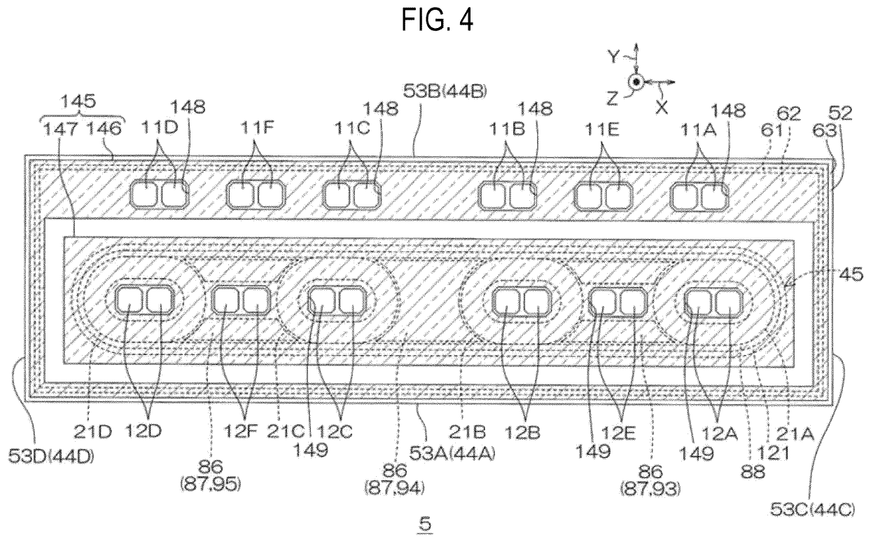

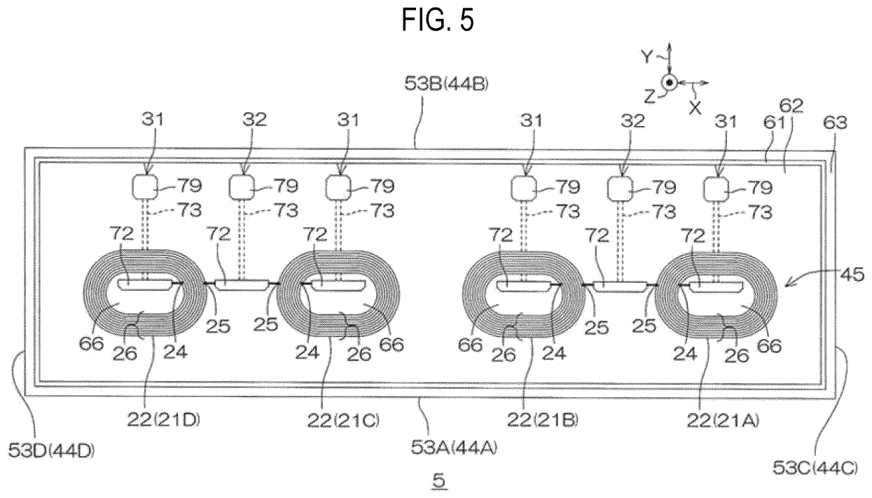

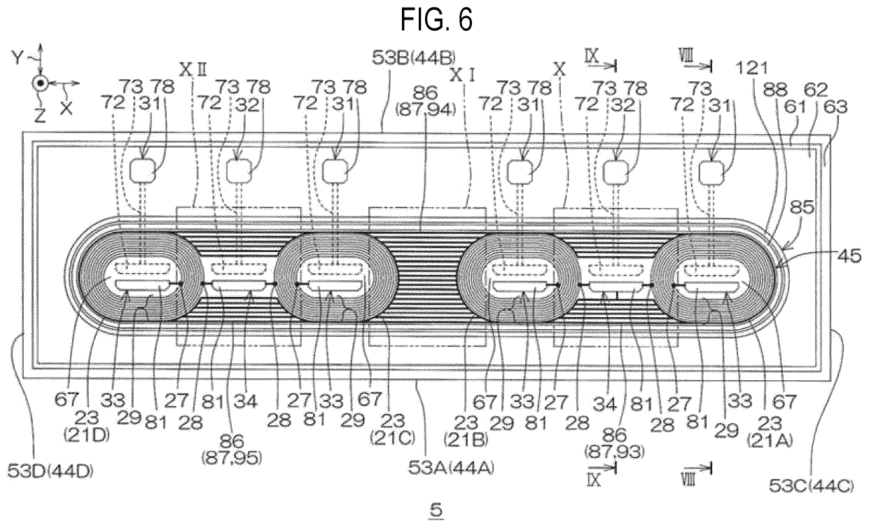

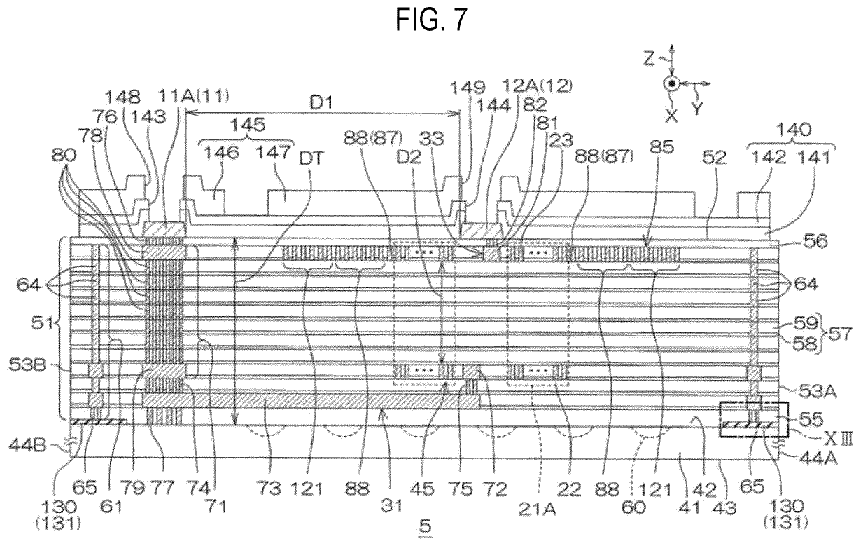

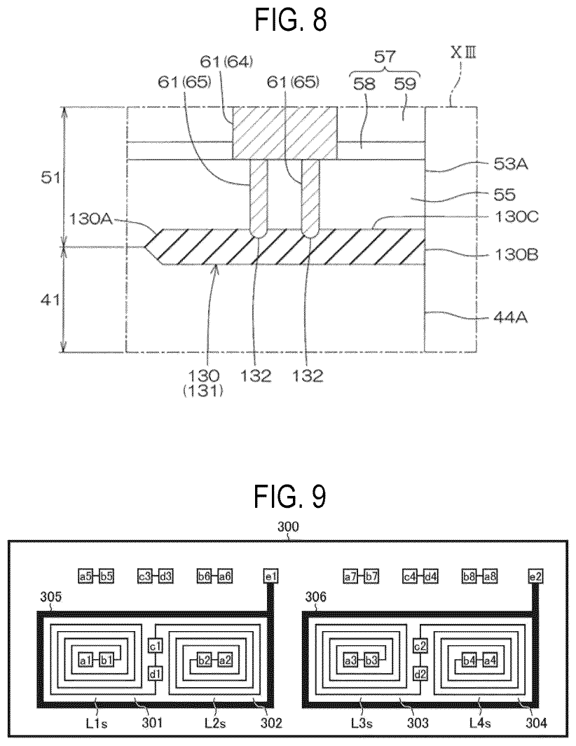

FIG. 3 is a perspective view showing a semiconductor device 5 used as a two-channel transformer chip. FIG. 4 is a plan view of the semiconductor device 5 shown in FIG. 3. FIG. 5 is a plan view showing a layer in which a low-potential coil 22 (corresponding to the primary side coil of the transformer) is formed in the semiconductor device 5 shown in FIG. 3. FIG. 6 is a plan view showing a layer in which a high-potential coil 23 (corresponding to the secondary side coil of the transformer) is formed in the semiconductor device 5 shown in FIG. 3. FIG. 7 is a cross-sectional view taken along line VIII-VIII shown in FIG. 6. FIG. 8 is an enlarged view of region XIII shown in FIG. 7, and shows an isolation structure 130.

Referring to FIGS. 3 to 7, the semiconductor device 5 includes a semiconductor chip 41 having a rectangular parallelepiped shape. The semiconductor chip 41 includes at least one selected from the group of silicon, a wide band gap semiconductor, and a compound semiconductor.

The wide band gap semiconductor includes a semiconductor that exceeds a band gap of silicon (approximately 1.12 eV). The band gap of the wide band gap semiconductor is preferably 2.0 eV or more. The wide band gap semiconductor may be SiC (silicon carbide). The compound semiconductor may be a group III-V compound semiconductor. The compound semiconductor may include at least one selected from the group of AlN (aluminum nitride), InN (indium nitride), GaN (gallium nitride), and GaAs (gallium arsenide).

In the present embodiment, the semiconductor chip 41 includes a semiconductor substrate made of silicon. The semiconductor chip 41 may be an epitaxial substrate having a laminated structure including a semiconductor substrate made of silicon and an epitaxial layer made of silicon. A conductivity type of the semiconductor substrate may be an n-type or a p-type. The epitaxial layer may be of an n-type or of a p-type.

The semiconductor chip 41 has a first main surface 42 on one side, a second main surface 43 on the other side, and chip sidewalls 44A to 44D connecting the first main surface 42 and the second main surface 43. The first main surface 42 and the second main surface 43 are formed in a quadrangular shape (rectangular shape in the present embodiment) in a plan view as seen from their normal direction Z (hereinafter, referred to as a “plan view”).

The chip sidewalls 44A to 44D include a first chip sidewall 44A, a second chip sidewall 44B, a third chip sidewall 44C, and a fourth chip sidewall 44D. The first chip sidewall 44A and the second chip sidewall 44B form long sides of the semiconductor chip 41. The first chip sidewall 44A and the second chip sidewall 44B extend along a first direction X and face a second direction Y. The third chip sidewall 44C and the fourth chip sidewall 44D form short sides of the semiconductor chip 41. The third chip sidewall 44C and the fourth chip sidewall 44D extend in the second direction Y and face the first direction X. The chip sidewalls 44A to 44D are ground surfaces.

The semiconductor device 5 further includes an insulating layer 51 formed on the first main surface 42 of the semiconductor chip 41. The insulating layer 51 has an insulating main surface 52 and insulating sidewalls 53A to 53D. The insulating main surface 52 is formed in a quadrangular shape (rectangular shape in the present embodiment) matching the first main surface 42 in a plan view. The insulating main surface 52 extends parallel to the first main surface 42.

The insulating sidewalls 53A to 53D include a first insulating sidewall 53A, a second insulating sidewall 53B, a third insulating sidewall 53C, and a fourth insulating sidewall 53D. The insulating sidewalls 53A to 53D extend from a peripheral edge of the insulating main surface 52 toward the semiconductor chip 41 and are connected to the chip sidewalls 44A to 44D. Specifically, the insulating sidewalls 53A to 53D are formed flush with the chip sidewalls 44A to 44D. The insulating sidewalls 53A to 53D form ground surfaces flush with the chip sidewalls 44A to 44D.

The insulating layer 51 has a multi-layer insulating laminated structure including a bottom insulating layer 55, a top insulating layer 56, and a plurality of (eleven layers in the present embodiment) interlayer insulating layers 57. The bottom insulating layer 55 is an insulating layer that directly covers the first main surface 42. The top insulating layer 56 is an insulating layer that forms the insulating main surface 52. The plurality of interlayer insulating layers 57 are insulating layers interposed between the bottom insulating layer 55 and the top insulating layer 56. In the present embodiment, the bottom insulating layer 55 has a single layer structure containing silicon oxide. In the present embodiment, the top insulating layer 56 has a single layer structure containing silicon oxide. A thickness of the bottom insulating layer 55 and a thickness of the top insulating layer 56 may each be 1 μm or more and 3 μm or less (for example, about 2 μm).

The plurality of interlayer insulating layers 57 each have a laminated structure including a first insulating layer 58 on the side of the bottom insulating layer 55 and a second insulating layer 59 on the side of the top insulating layer 56. The first insulating layer 58 may contain silicon nitride. The first insulating layer 58 is formed as an etching stopper layer for the second insulating layer 59. A thickness of the first insulating layer 58 may be 0.1 μm or more and 1 μm or less (for example, about 0.3 μm).

The second insulating layer 59 is formed on the first insulating layer 58. The second insulating layer 59 contains an insulating material different from that of the first insulating layer 58. The second insulating layer 59 may contain silicon oxide. A thickness of the second insulating layer 59 may be 1 μm or more and 3 μm or less (for example, about 2 μm). The thickness of the second insulating layer 59 preferably exceeds the thickness of the first insulating layer 58.

A total thickness DT of the insulating layer 51 may be 5 μm or more and 50 μm or less. The total thickness DT of the insulating layers 51 and the number of layers of the interlayer insulating layers 57 are arbitrary and are adjusted according to a dielectric withstand voltage (dielectric breakdown tolerance) to be achieved. Insulating materials for the bottom insulating layer 55, the top insulating layer 56, and the interlayer insulating layers 57 are arbitrary and are not limited to specific insulating materials.

The semiconductor device 5 includes a first functional device 45 formed in the insulating layer 51. The first functional device 45 includes one or more (plurality of, in the present embodiment) transformers 21 (corresponding to the above-described transformers). That is, the semiconductor device 5 is a multi-channel device including a plurality of transformers 21. The plurality of transformers 21 are formed in an inner side of the insulating layer 51 at an interval from the insulating sidewalls 53A to 53D. The plurality of transformers 21 are formed at an interval in the first direction X.

Specifically, the plurality of transformers 21 include a first transformer 21A, a second transformer 21B, a third transformer 21C, and a fourth transformer 21D formed in this order from the side of the insulating sidewall 53C toward the side of the insulating sidewall 53D in a plan view. The plurality of transformers 21A to 21D have a same structure. The structure of the first transformer 21A will be described below as an example. Descriptions of structures of the second transformer 21B, the third transformer 21C, and the fourth transformer 21D are omitted because the description of the structure of the first transformer 21A is applied.

Referring to FIGS. 5 to 7, the first transformer 21A includes a low-potential coil 22 and a high-potential coil 23. The low-potential coil 22 is formed in the insulating layer 51. The high-potential coil 23 is formed in the insulating layer 51 so as to face the low-potential coil 22 in the normal direction Z. In the present embodiment, the low-potential coil 22 and the high-potential coil 23 are formed in a region interposed between the bottom insulating layer 55 and the top insulating layer 56 (that is, in the plurality of interlayer insulating layers 57).

The low-potential coil 22 is formed on the side of the bottom insulating layer 55 (the semiconductor chip 41) within the insulating layer 51, and the high-potential coil 23 is formed on the side of the top insulating layer 56 (the insulating main surface 52) with respect to the low-potential coil 22 within the insulating layer 51. That is, the high-potential coil 23 faces the semiconductor chip 41 with the low-potential coil 22 interposed therebetween. The low-potential coil 22 and the high-potential coil 23 may be arranged at any position. The high-potential coil 23 may also face the low-potential coil 22 with one or more interlayer insulating layers 57 interposed therebetween.

A distance between the low-potential coil 22 and the high-potential coil 23 (that is, the number of layers of the interlayer insulation layers 57) is appropriately adjusted according to a dielectric withstand voltage and an electric field intensity between the low-potential coil 22 and the high-potential coil 23. In the present embodiment, the low-potential coil 22 is formed at the third interlayer insulating layer 57 counted from the side of the bottom insulating layer 55. In the present embodiment, the high-potential coil 23 is formed at the first interlayer insulating layer 57 counted from the side of the top insulating layer 56.

The low-potential coil 22 is embedded through the first insulating layer 58 and the second insulating layer 59 in the interlayer insulating layer 57. The low-potential coil 22 includes a first inner end 24, a first outer end 25, and a first spiral portion 26 spirally pulled around between the first inner end 24 and the first outer end 25. The first spiral portion 26 is pulled around in a spiral shape extending in an elliptical shape (oval shape) in a plan view. A portion forming an innermost peripheral edge of the first spiral portion 26 defines an elliptical first inner region 66 in a plan view.

The number of turns of the first spiral portion 26 may be 5 or more and 30 or less. A width of the first spiral portion 26 may be 0.1 μm or more and 5 μm or less. The width of the first spiral portion 26 is preferably 1 μm or more and 3 μm or less. The width of the first spiral portion 26 is defined by a width in a direction orthogonal to the spiral direction. A first winding pitch of the first spiral portion 26 may be 0.1 μm or more and 5 μm or less. The first winding pitch is preferably 1 μm or more and 3 μm or less. The first winding pitch is defined by a distance between two adjacent portions of the first spiral portion 26 in a direction orthogonal to the spiral direction.

A winding shape of the first spiral portion 26 and a planar shape of the first inner region 66 are arbitrary and are not limited to the shapes shown in FIG. 5 and the like. The first spiral portion 26 may be wound in a polygonal shape such as a triangular shape or a quadrangular shape, or a circular shape in a plan view. The first inner region 66 may be defined in a polygonal shape such as a triangular shape or a quadrangular shape, or a circular shape in a plan view according to the winding shape of the first spiral portion 26.

The low-potential coil 22 may contain at least one selected from the group of titanium, titanium nitride, copper, aluminum, and tungsten. The low-potential coil 22 may have a laminated structure including a barrier layer and a main body layer. The barrier layer defines a recess space within the interlayer insulating layer 57. The barrier layer may contain at least one selected from the group of titanium and titanium nitride. The main body layer may contain at least one selected from the group of copper, aluminum, and tungsten.

The high-potential coil 23 is embedded through the first insulating layer 58 and the second insulating layer 59 in the interlayer insulating layer 57. The high-potential coil 23 includes a second inner end 27, a second outer end 28, and a second spiral portion 29 spirally pulled around between the second inner end 27 and the second outer end 28. The second spiral portion 29 is pulled around in a spiral shape extending in an elliptical shape (oval shape) in a plan view. In the present embodiment, a portion forming an innermost peripheral edge of the second spiral portion 29 defines an elliptical second inner region 67 in a plan view. The second inner region 67 of the second spiral portion 29 faces the first inner region 66 of the first spiral portion 26 in the normal direction Z.

The number of turns of the second spiral portion 29 may be 5 or more and 30 or less. The number of turns of the second spiral portion 29 relative to the number of turns of the first spiral portion 26 is adjusted according to a voltage value to be boosted. The number of turns of the second spiral portion 29 preferably exceeds the number of turns of the first spiral portion 26. Of course, the number of turns of the second spiral portion 29 may be less than the number of turns of the first spiral portion 26 or may be equal to the number of turns of the first spiral portion 26.

A width of the second spiral portion 29 may be 0.1 μm or more and 5 μm or less. The width of the second spiral portion 29 is preferably 1 μm or more and 3 μm or less. The width of the second spiral portion 29 is defined by a width in a direction orthogonal to the spiral direction. The width of the second spiral portion 29 is preferably equal to the width of the first spiral portion 26.

A second winding pitch of the second spiral portion 29 may be 0.1 μm or more and 5 μm or less. The second winding pitch is preferably 1 μm or more and 3 μm or less. The second winding pitch is defined by a distance between two adjacent portions of the second spiral portion 29 in a direction orthogonal to the spiral direction. The second winding pitch of the second spiral portion 29 is preferably equal to the first winding pitch of the first spiral portion 26.

A winding shape of the second spiral portion 29 and a planar shape of the second inner region 67 are arbitrary and are not limited to the shapes shown in FIG. 6 and the like. The second spiral portion 29 may be wound in a polygonal shape such as a triangular shape or a quadrangular shape, or a circular shape in a plan view. The second inner region 67 may be partitioned into a polygonal shape such as a triangular shape or a quadrangular shape, or a circular shape in a plan view according to the winding shape of the second spiral portion 29.

The high-potential coil 23 is preferably made of the same conductive material as the low-potential coil 22. That is, similar to the low-potential coil 22, the high-potential coil 23 preferably includes a barrier layer and a main body layer.

Referring to FIG. 4, the semiconductor device 5 includes a plurality of (twelve in this figure) low-potential terminals 11 and a plurality of (twelve in this figure) high-potential terminals 12. The plurality of low-potential terminals 11 are electrically connected to the low-potential coils 22 of the corresponding transformers 21A to 21D, respectively. The plurality of high-potential terminals 12 are electrically connected to the high-potential coils 23 of the corresponding transformers 21A to 21D, respectively.

The plurality of low-potential terminals 11 are formed on the insulating main surface 52 of the insulating layer 51. Specifically, the plurality of low-potential terminals 11 are formed in a region on the side of the insulating sidewall 53B at an interval from the plurality of transformers 21A to 21D in the second direction Y and are arranged at an interval in the first direction X.

The plurality of low-potential terminals 11 include a first low-potential terminal 11A, a second low-potential terminal 11B, a third low-potential terminal 11C, a fourth low-potential terminal 11D, a fifth low-potential terminal 11E, and a sixth low-potential terminal 11F. In the present embodiment, the plurality of low-potential terminals 11A to 11F are each formed in pairs. The number of low-potential terminals 11A to 11F is arbitrary.

The first low-potential terminal 11A faces the first transformer 21A in the second direction Y in a plan view. The second low-potential terminal 11B faces the second transformer 21B in the second direction Y in a plan view. The third low-potential terminal 11C faces the third transformer 21C in the second direction Y in a plan view. The fourth low-potential terminal 11D faces the fourth transformer 21D in the second direction Y in a plan view. The fifth low-potential terminal 11E is formed in a region between the first low-potential terminal 11A and the second low-potential terminal 11B in a plan view. The sixth low-potential terminal 11F is formed in a region between the third low-potential terminal 11C and the fourth low-potential terminal 11D in a plan view.

The first low-potential terminal 11A is electrically connected to the first inner end 24 of the first transformer 21A (the low-potential coil 22). The second low-potential terminal 11B is electrically connected to the first inner end 24 of the second transformer 21B (the low-potential coil 22). The third low-potential terminal 11C is electrically connected to the first inner end 24 of the third transformer 21C (the low-potential coil 22). The fourth low-potential terminal 11D is electrically connected to the first inner end 24 of the fourth transformer 21D (the low-potential coil 22).

The fifth low-potential terminal 11E is electrically connected to the first outer end 25 of the first transformer 21A (the low-potential coil 22) and the first outer end 25 of the second transformer 21B (the low-potential coil 22). The sixth low-potential terminal 11F is electrically connected to the first outer end 25 of the third transformer 21C (the low-potential coil 22) and the first outer end 25 of the fourth transformer 21D (the low-potential coil 22).

The plurality of high-potential terminals 12 are formed on the insulating main surface 52 of the insulating layer 51 at an interval from the plurality of low-potential terminals 11. Specifically, the plurality of high-potential terminals 12 are formed in a region on the side of the insulating sidewall 53A at an interval from the plurality of low-potential terminals 11 in the second direction Y and are arranged at an interval in the first direction X.

The plurality of high-potential terminals 12 are formed in regions close to the corresponding transformers 21A to 21D, respectively, in a plan view. When the high-potential terminal 12 is close to the transformers 21A to 21D, it means that a distance between the high-potential terminal 12 and the transformer 21 is less than a distance between the low-potential terminal 11 and the high-potential terminal 12 in a plan view.

Specifically, the plurality of high-potential terminals 12 are formed at an interval along the first direction X so as to face the plurality of transformers 21A to 21D along the first direction X in a plan view. More specifically, the plurality of high-potential terminals 12 are formed at an interval along the first direction X so as to be located in a region between the second inner region 67 of the high-potential coil 23 and an adjacent high-potential coil 23 in a plan view. As a result, the plurality of high-potential terminals 12 are arranged in a row side by side with the plurality of transformers 21A to 21D in the first direction X in a plan view.

The plurality of high-potential terminals 12 includes a first high-potential terminal 12A, a second high-potential terminal 12B, a third high-potential terminal 12C, a fourth high-potential terminal 12D, a fifth high-potential terminal 12E, and a sixth high-potential terminal 12F. In the present embodiment, the plurality of high-potential terminals 12A to 12F are each formed in pairs. The number of high-potential terminals 12A to 12F is arbitrary.

The first high-potential terminal 12A is formed in the second inner region 67 of the first transformer 21A (the high-potential coil 23) in a plan view. The second high-potential terminal 12B is formed in the second inner region 67 of the second transformer 21B (the high-potential coil 23) in a plan view. The third high-potential terminal 12C is formed in the second inner region 67 of the third transformer 21C (the high-potential coil 23) in a plan view. The fourth high-potential terminal 12D is formed in the second inner region 67 of the fourth transformer 21D (the high-potential coil 23) in a plan view. The fifth high-potential terminal 12E is formed in a region between the first transformer 21A and the second transformer 21B in a plan view. The sixth high-potential terminal 12F is formed in a region between the third transformer 21C and the fourth transformer 21D in a plan view.

The first high-potential terminal 12A is electrically connected to the second inner end 27 of the first transformer 21A (the high-potential coil 23). The second high-potential terminal 12B is electrically connected to the second inner end 27 of the second transformer 21B (the high-potential coil 23). The third high-potential terminal 12C is electrically connected to the second inner end 27 of the third transformer 21C (the high-potential coil 23). The fourth high-potential terminal 12D is electrically connected to the second inner end 27 of the fourth transformer 21D (the high-potential coil 23).

The fifth high-potential terminal 12E is electrically connected to the second outer end 28 of the first transformer 21A (the high-potential coil 23) and the second outer end 28 of the second transformer 21B (the high-potential coil 23). The sixth high-potential terminal 12F is electrically connected to the second outer end 28 of the third transformer 21C (the high-potential coil 23) and the second outer end 28 of the fourth transformer 21D (the high-potential coil 23).

Referring to FIGS. 5 to 7, the semiconductor device 5 includes a first low-potential wiring 31, a second low-potential wiring 32, a first high-potential wiring 33, and a second high-potential wiring 34 formed in the insulating layer 51. In the present embodiment, a plurality of first low-potential wirings 31, a plurality of second low-potential wirings 32, a plurality of first high-potential wirings 33, and a plurality of second high-potential wirings 34 are formed.

The first low-potential wiring 31 and the second low-potential wiring 32 fix the low-potential coil 22 of the first transformer 21A and the low-potential coil 22 of the second transformer 21B to the same potential. Further, the first low-potential wiring 31 and the second low-potential wiring 32 fix the low-potential coil 22 of the third transformer 21C and the low-potential coil 22 of the fourth transformer 21D to the same potential. In present embodiment, the first low-potential wiring 31 and the second low-potential wiring 32 fix all the low-potential coils 22 of the transformers 21A to 21D to the same potential.

The first high-potential wiring 33 and the second high-potential wiring 34 fix the high-potential coil 23 of the first transformer 21A and the high-potential coil 23 of the second transformer 21B to the same potential. Further, the first high-potential wiring 33 and the second high-potential wiring 34 fix the high-potential coil 23 of the third transformer 21C and the high-potential coil 23 of the fourth transformer 21D to the same potential. In the present embodiment, the first high-potential wiring 33 and the second high-potential wiring 34 fix all the high-potential coils 23 of the transformers 21A to 21D at the same potential.

The plurality of first low-potential wirings 31 are electrically connected to the corresponding low-potential terminals 11A to 11D and the first inner ends 24 of the corresponding transformers 21A to 21D (the low-potential coils 22), respectively. The plurality of first low-potential wirings 31 have a same structure. The structure of the first low-potential wiring 31 connected to the first low-potential terminal 11A and the first transformer 21A will be described below as an example. Description of the structures of other first low-potential wirings 31 is omitted because the description of the structure of the first low-potential wiring 31 connected to the first transformer 21A is applied.

The first low-potential wiring 31 includes a through-wiring 71, a low-potential connection wiring 72, a lead-out wiring 73, a first connection plug electrode 74, a second connection plug electrode 75, one or more (plurality of, in the present embodiment) pad plug electrodes 76, and one or more (plurality of, in the present embodiment) substrate plug electrodes 77.

The through-wiring 71, the low-potential connection wiring 72, the lead-out wiring 73, the first connection plug electrode 74, the second connection plug electrode 75, the pad plug electrodes 76, and the substrate plug electrodes 77 are preferably made of the same conductive material as the low-potential coil 22 and the like. That is, similar to the low-potential coil 22 and the like, the through-wiring 71, the low-potential connection wiring 72, the lead-out wiring 73, the first connection plug electrode 74, the second connection plug electrode 75, the pad plug electrodes 76, and the substrate plug electrodes 77 preferably each include a barrier layer and a main body layer.

The through-wiring 71 penetrates the plurality of interlayer insulating layers 57 in the insulating layer 51 and extends in a columnar shape along the normal direction Z. In the present embodiment, the through-wiring 71 is formed in a region between the bottom insulating layer 55 and the top insulating layer 56 in the insulating layer 51. The through-wiring 71 has an upper end portion on the side of the top insulating layer 56 and a lower end portion on the side of the bottom insulating layer 55. The upper end portion of the through-wiring 71 is formed in the same interlayer insulating layer 57 as the high-potential coil 23 and is covered with the top insulating layer 56. The lower end portion of the through-wiring 71 is formed on the same interlayer insulating layer 57 as the low-potential coil 22.

In the present embodiment, the through-wiring 71 includes a first electrode layer 78, a second electrode layer 79, and a plurality of wiring plug electrodes 80. In the through-wiring 71, the first electrode layer 78, the second electrode layer 79, and the wiring plug electrodes 80 are made of the same conductive material as the low-potential coil 22 and the like. That is, similar to the low-potential coil 22 and the like, the first electrode layer 78, the second electrode layer 79, and the wiring plug electrodes 80 include a barrier layer and a main body layer.

The first electrode layer 78 forms the upper end portion of the through-wiring 71. The second electrode layer 79 forms the lower end portion of the through-wiring 71. The first electrode layer 78 is formed in an island shape and faces the low-potential terminal 11 (the first low-potential terminal 11A) in the normal direction Z. The second electrode layer 79 is formed in an island shape and faces the first electrode layer 78 in the normal direction Z.

The plurality of wiring plug electrodes 80 are buried in the plurality of interlayer insulating layers 57, respectively, located between the first electrode layer 78 and the second electrode layer 79. The plurality of wiring plug electrodes 80 are laminated from the bottom insulating layer 55 toward the top insulating layer 56 so as to be electrically connected to each other, and electrically connect the first electrode layer 78 and the second electrode layer 79 to each other. The plurality of wiring plug electrodes 80 each have a plane area less than a plane area of the first electrode layer 78 and a plane area of the second electrode layer 79.

The number of layers of the plurality of wiring plug electrodes 80 is equal to the number of layers of the plurality of interlayer insulating layers 57. In the present embodiment, although six wiring plug electrodes 80 are buried in each interlayer insulating layer 57, the number of wiring plug electrodes 80 buried in each interlayer insulating layer 57 is arbitrary. Of course, one or more wiring plug electrodes 80 penetrating the plurality of interlayer insulating layers 57 may be formed.

The low-potential connection wiring 72 is formed in the first inner region 66 of the first transformer 21A (the low-potential coil 22) in the same interlayer insulating layer 57 as the low-potential coil 22. The low-potential connection wiring 72 is formed in an island shape and faces the high-potential terminal 12 (the first high-potential terminal 12A) in the normal direction Z. The low-potential connection wiring 72 preferably has a plane area exceeding the plane area of the wiring plug electrode 80. The low-potential connection wiring 72 is electrically connected to the first inner end 24 of the low-potential coil 22.

The lead-out wiring 73 is formed in a region between the semiconductor chip 41 and the through-wiring 71 within the interlayer insulating layer 57. In the present embodiment, the lead-out wiring 73 is formed within the first interlayer insulating layer 57 counted from the bottom insulating layer 55. The lead-out wiring 73 includes a first end portion on one side, a second end portion on the other side, and a wiring portion connecting the first end portion and the second end portion. The first end portion of the lead-out wiring 73 is located in a region between the semiconductor chip 41 and the lower end portion of the through-wiring 71. The second end portion of the lead-out wiring 73 is located in a region between the semiconductor chip 41 and the low-potential connection wiring 72. The wiring portion extends along the first main surface 42 of the semiconductor chip 41 and extends in a strip shape in a region between the first end portion and the second end portion.

The first connection plug electrode 74 is formed in a region between the through-wiring 71 and the lead-out wiring 73 within the interlayer insulating layer 57 and is electrically connected to the through-wiring 71 and the first end portion of the lead-out wiring 73. The second connection plug electrode 75 is formed in a region between the low-potential connection wiring 72 and the lead-out wiring 73 within the interlayer insulating layer 57 and is electrically connected to the low-potential connection wiring 72 and the second end portion of the lead-out wiring 73.

The plurality of pad plug electrodes 76 are formed in a region between the low-potential terminal 11 (the first low-potential terminal 11A) and the through-wiring 71 within the top insulating layer 56 and are each electrically connected to the low-potential terminal 11 and the upper end portion of the through-wiring 71. The plurality of substrate plug electrodes 77 are formed in a region between the semiconductor chip 41 and the lead-out wiring 73 within the bottom insulating layer 55. In the present embodiment, the substrate plug electrodes 77 are formed in a region between the semiconductor chip 41 and the first end portion of the lead-out wirings 73 and are electrically connected to the semiconductor chip 41 and the first end portion of the lead-out wiring 73, respectively.

Referring to FIGS. 6 and 7, the plurality of first high-potential wirings 33 are electrically connected to the corresponding high-potential terminals 12A to 12D and the second inner end portions 27 of the corresponding transformers 21A to 21D (the high-potential coils 23). The plurality of first high-potential wirings 33 have the same structure. A structure of the first high-potential wiring 33 connected to the first high-potential terminal 12A and the first transformer 21A will be described below as an example. Description of structures of other first high-potential wirings 33 is omitted because the description of the structure of the first high-potential wiring 33 connected to the first transformer 21A is applied.

The first high-potential wiring 33 includes a high-potential connection wiring 81 and one or more (plurality of, in the present embodiment) pad plug electrodes 82. The high-potential connection wiring 81 and the pad plug electrodes 82 are preferably made of the same conductive material as the low-potential coil 22 and the like. That is, similar to the low-potential coil 22 and the like, the high-potential connection wiring 81 and the pad plug electrodes 82 preferably include a barrier layer and a main body layer.

The high-potential connection wiring 81 is formed in the second inner region 67 of the high-potential coil 23 in the same interlayer insulating layer 57 as the high-potential coil 23. The high-potential connection wiring 81 is formed in an island shape and faces the high-potential terminal 12 (the first high-potential terminal 12A) in the normal direction Z. The high-potential connection wiring 81 is electrically connected to the second inner end 27 of the high-potential coil 23. The high-potential connection wiring 81 is formed at an interval from the low-potential connection wiring 72 in a plan view and does not face the low-potential connection wiring 72 in the normal direction Z. As a result, an insulation distance between the low-potential connection wiring 72 and the high-potential connection wiring 81 increases, and the dielectric withstand voltage of the insulation layer 51 increases accordingly.

The plurality of pad plug electrodes 82 are formed in a region between the high-potential terminal 12 (the first high-potential terminal 12A) and the high-potential connection wiring 81 within the top insulating layer 56 and are electrically connected to the high-potential terminal 12 and the high-potential connection wiring 81. Each of the plurality of pad plug electrodes 82 has a plane area smaller than a plane area of the high-potential connection wiring 81 in a plan view.

Referring to FIG. 7, a distance D1 between the low-potential terminal 11 and the high-potential terminal 12 preferably exceeds a distance D2 between the low-potential coil 22 and the high-potential coil 23 (D2<D1). The distance D1 preferably exceeds a total thickness DT of the plurality of interlayer insulating layers 57 (DT<D1). A ratio D2/D1 of the distance D2 to the distance D1 may be 0.01 or more and 0.1 or less. The distance D1 is preferably 100 μm or more and 500 μm or less. The distance D2 may be 1 μm or more and 50 μm or less. The distance D2 is preferably 5μm or more and 25 μm or less. Values of the distance D1 and the distance D2 are arbitrary and are appropriately adjusted according to a dielectric withstand voltage to be achieved.

Referring to FIGS. 6 and 7, the semiconductor device 5 includes a dummy pattern 85 buried in the insulating layer 51 so as to be located around the transformers 21A to 21D in a plan view.

The dummy pattern 85 is formed in a pattern (discontinuous pattern) different from those of the high-potential coil 23 and the low-potential coil 22 and is independent of the transformers 21A to 21D. In other words, the dummy pattern 85 does not function as the transformers 21A to 21D. The dummy pattern 85 is formed as a shield conductor layer that shields an electric field between the low-potential coil 22 and the high-potential coil 23 in the transformers 21A to 21D and suppresses electric field concentration on the high-potential coil 23. In the present embodiment, the dummy pattern 85 is pulled around with a line density equal to a line density of the high-potential coil 23 per unit area. The line density of the dummy pattern 85 being equal to the line density of the high-potential coil 23 means that the line density of the dummy pattern 85 falls within ±20% of the line density of the high-potential coil 23.

A depth position of the dummy pattern 85 inside the insulating layer 51 is arbitrary and is adjusted according to the electric field intensity to be alleviated. The dummy pattern 85 is preferably formed in a region closer to the high-potential coil 23 than the low-potential coil 22 with respect to the normal direction Z. When the dummy pattern 85 is closer to the high-potential coil 23 with respect to the normal direction Z, it means that a distance between the dummy pattern 85 and the high-potential coil 23 is less than a distance between the dummy pattern 85 and the low-potential coil 22 with respect to the normal direction Z.

In this case, the electric field concentration on the high-potential coil 23 can be appropriately suppressed. With respect to the normal direction Z, as the distance between the dummy pattern 85 and the high-potential coil 23 is reduced, the electric field concentration on the high-potential coil 23 can be suppressed. The dummy pattern 85 is preferably formed in the same interlayer insulating layer 57 as the high-potential coil 23. In this case, the electric field concentration on the high-potential coil 23 can be suppressed more appropriately. The dummy pattern 85 includes a plurality of dummy patterns having different electrical states. The dummy pattern 85 may include a high-potential dummy pattern.

A depth position of a high-potential dummy pattern 86 inside the insulating layer 51 is arbitrary and is adjusted according to the electric field intensity to be alleviated. The high-potential dummy pattern 86 is preferably formed in a region closer to the high-potential coil 23 than the low-potential coil 22 with respect to the normal direction Z. When the high-potential dummy pattern 86 is closer to the high-potential coil 23 with respect to the normal direction Z, it means that a distance between the high-potential dummy pattern 86 and the high-potential coil 23 is less than a distance between the high-potential dummy pattern 86 and the low-potential coil 23 with respect to the normal direction Z2.

The dummy pattern 85 includes a floating dummy pattern formed in an electrically floating state within the insulating layer 51 so as to be located around the transformers 21A to 21D.

In the present embodiment, the floating dummy pattern is pulled around in a dense line shape so as to partially cover and partially expose a region around the high-potential coil 23 in a plan view. The floating dummy pattern may be formed in an ended shape, or may be formed in an endless shape.

The depth position of the floating dummy pattern inside the insulating layer 51 is arbitrary and is adjusted according to the electric field intensity to be alleviated.

The number of floating lines is arbitrary and is adjusted according to the electric field to be alleviated. The floating dummy pattern may include a plurality of floating lines.

Referring to FIG. 7, the semiconductor device 5 includes a second functional device 60 formed on the first main surface 42 of the semiconductor chip 41 in a device region 62. The second functional device 60 is formed by using a surface layer portion of the first main surface 42 of the semiconductor chip 41 and/or a region over the first main surface 42 of the semiconductor chip 41, and is covered with the insulating layer 51 (the bottom insulating layer 55). In FIG. 7, the second functional device 60 is simply indicated by a broken line shown in the surface layer portion of the first main surface 42.

The second functional device 60 is electrically connected to the low-potential terminal 11 via a low-potential wiring and is electrically connected to the high-potential terminal 12 via a high-potential wiring. The low-potential wiring has the same structure as the first low-potential wiring 31 (the second low-potential wiring 32) except that it is pulled around in the insulating layer 51 so as to be connected to the second functional device 60. The high-potential wiring has the same structure as the first high-potential wiring 33 (the second high-potential wiring 34) except that it is pulled around in the insulating layer 51 so as to be connected to the second functional device 60. The detailed description of the low-potential wiring and the high-potential wiring related to the second functional device 60 is omitted.

The second functional device 60 may include at least one selected from the group of a passive device, a semiconductor rectifying device, and a semiconductor switching device. The second functional device 60 may include a circuit network in which at least two or more selected from the group of the passive device, the semiconductor rectifying device, and the semiconductor switching device are selectively combined. The circuit network may form a part or all of an integrated circuit.

The passive device may include a semiconductor passive device. The passive device may include one or both of a resistor and a capacitor. The semiconductor rectifying device may include at least one selected from the group of a pn junction diode, a PIN diode, a Zener diode, a Schottky barrier diode, and a fast recovery diode. The semiconductor switching device may include at least one selected from the group of a bipolar junction transistor (BJT), a metal insulator semiconductor field effect transistor (MISFET), an insulated gate bipolar junction transistor (IGBT), and a junction field effect transistor (JFET).

Referring to FIGS. 5 to 7, the semiconductor device 5 further includes a seal conductor 61 buried in the insulating layer 51. The seal conductor 61 is buried in the insulating layer 51 in a wall shape at an interval from the insulating sidewalls 53A to 53D in a plan view and partitions the insulating layer 51 into a device region 62 and an outer region 63. The seal conductor 61 suppresses entry of moisture and cracks from the outer region 63 into the device region 62.

The device region 62 is a region including the first functional device 45 (the plurality of transformers 21), the second functional device 60, the plurality of low-potential terminals 11, the plurality of high-potential terminals 12, the first low-potential wiring 31, the second low-potential wiring 32, the first high-potential wiring 33, the second high-potential wiring 34, and the dummy pattern 85. The outer region 63 is a region outside the device region 62.

The seal conductor 61 is electrically separated from the device region 62. Specifically, the seal conductor 61 is electrically separated from the first functional device 45 (the plurality of transformers 21), the second functional device 60, the plurality of low-potential terminals 11, the plurality of high-potential terminals 12, the first low-potential wiring 31, the second low-potential wiring 32, the first high-potential wiring 33, the second high-potential wiring 34, and the dummy pattern 85. More specifically, the seal conductor 61 is fixed in an electrically floating state. The seal conductor 61 does not form a current path connected to the device region 62.

The seal conductor 61 is formed in a strip shape along the insulating sidewalls 53A to 53D in a plan view. In the present embodiment, the seal conductor 61 is formed in a quadrangular annular shape (specifically, a rectangular annular shape) in a plan view. Thus, the seal conductor 61 defines a quadrangular (specifically, rectangular) device region 62 in a plan view. Further, the seal conductor 61 defines a quadrangular annular (specifically, rectangular annular) outer region 63 surrounding the device region 62 in a plan view.

Specifically, the seal conductor 61 has an upper end portion on the side of the insulating main surface 52, a lower end portion on the side of the semiconductor chip 41, and a wall portion extending in a wall shape between the upper end portion and the lower end portion. In the present embodiment, the upper end portion of the seal conductor 61 is formed at an interval from the insulating main surface 52 toward the semiconductor chip 41 and is located within the insulating layer 51. In the present embodiment, the upper end portion of the seal conductor 61 is covered with the top insulating layer 56. The upper end portion of the seal conductor 61 may be covered with one or more interlayer insulation layers 57. The upper end portion of the seal conductor 61 may be exposed from the top insulating layer 56. The lower end portion of the seal conductor 61 is formed at an interval from the semiconductor chip 41 toward the upper end portion.

In this way, in the present embodiment, the seal conductor 61 is buried in the insulating layer 51 so as to be located on the side of the semiconductor chip 41 with respect to the plurality of low-potential terminals 11 and the plurality of high-potential terminals 12. Further, the seal conductor 61 faces the first functional device 45 (the plurality of transformers 21), the first low-potential wiring 31, the second low-potential wiring 32, the first high-potential wiring 33, the second high-potential wiring 34, and the dummy pattern 85 within the insulating layer 51 in a direction parallel to the insulating main surface 52. The seal conductor 61 may face a portion of the second functional device 60 within the insulating layer 51 in a direction parallel to the insulating main surface 52.

The seal conductor 61 includes a plurality of seal plug conductors 64 and one or more (a plurality of, in the present embodiment) seal via conductors 65. The number of seal via conductors 65 is arbitrary. The uppermost seal plug conductor 64 of the plurality of seal plug conductors 64 forms the upper end portion of the seal conductor 61. Each of the plurality of seal via conductors 65 forms the lower end portion of the seal conductor 61. The seal plug conductor 64 and the seal via conductor 65 are preferably made of the same conductive material as the low-potential coil 22. That is, similar to the low-potential coil 22 and the like, the seal plug conductor 64 and the seal via conductor 65 preferably include a barrier layer and a main body layer.

The plurality of seal plug conductors 64 are embedded in the plurality of interlayer insulating layers 57, respectively, and are formed in a quadrangular annular shape (specifically, a rectangular annular shape) surrounding the device region 62 in a plan view. The plurality of seal plug conductors 64 are laminated from the bottom insulating layer 55 toward the top insulating layer 56 so as to be connected to each other. The number of layers of the plurality of seal plug conductors 64 is equal to the number of layers of the plurality of interlayer insulating layers 57. Of course, one or more seal plug conductors 64 penetrating the plurality of interlayer insulating layers 57 may be formed.

In a case where one annular seal conductor 61 is formed by an aggregation of the plurality of seal plug conductors 64, not all of the plurality of seal plug conductors 64 need to be formed in an annular shape. For example, at least one of the plurality of seal plug conductors 64 may be formed with an ended shape. Further, at least one of the plurality of seal plug conductors 64 may be divided into a plurality of ended stripe-shaped portions. However, considering a risk of moisture and cracks entering the device region 62, the plurality of seal plug conductors 64 are preferably formed in an endless shape (annular shape).

The plurality of seal via conductors 65 are formed in a region between the semiconductor chip 41 and the seal plug conductors 64 in the bottom insulating layer 55. The plurality of seal via conductors 65 are formed at an interval from the semiconductor chip 41 and are connected to the seal plug conductors 64. The plurality of seal via conductors 65 have a plane area less than the plane area of the seal plug conductors 64. When a single seal via conductor 65 is formed, the single seal via conductor 65 may have a plane area equal to or larger than the plane area of the seal plug conductors 64.

A width of the seal conductor 61 may be 0.1 μm or more and 10 μm or less. The width of the seal conductor 61 is preferably 1 μm or more and 5 μm or less. The width of the seal conductor 61 is defined by the width in a direction orthogonal to the extension direction of the seal conductor 61.

Referring to FIGS. 7 and 8, the semiconductor device 5 further includes an isolation structure 130 interposed between the semiconductor chip 41 and the seal conductor 61 to electrically isolate the seal conductor 61 from the semiconductor chip 41. The isolation structure 130 preferably includes an insulator. In the present embodiment, the isolation structure 130 includes a field insulating film 131 formed in the first main surface 42 of the semiconductor chip 41.

The field insulating film 131 includes at least one selected from the group of an oxide film (a silicon oxide film) and a nitride film (a silicon nitride film). The field insulating film 131 is preferably formed of a local oxidation of silicon (LOCOS) film which is an example of an oxide film formed by oxidation of the first main surface 42 of the semiconductor chip 41. A thickness of the field insulating film 131 is arbitrary as long as it can insulate the semiconductor chip 41 and the seal conductor 61 from each other. A thickness of the field insulating film 131 may be 0.1 μm or more and 5 μm or less.

An isolation structure 130 is formed on the first main surface 42 of the semiconductor chip 41 and extends in a strip shape along the seal conductor 61 in a plan view. In the present embodiment, the isolation structure 130 is formed in a quadrangular annular shape (specifically, a rectangular annular shape) in a plan view. The isolation structure 130 has a connection portion 132 to which the lower end portion (the seal via conductor 65) of the seal conductor 61 is connected. The connection portion 132 may form an anchor portion in which the lower end portion (the seal via conductor 65) of the seal conductor 61 is embedded toward the semiconductor chip 41 side. Of course, the connection portion 132 may be formed flush with the main surface of the isolation structure 130.

The isolation structure 130 includes an inner end portion 130A on the side of the device region 62, an outer end portion 130B on the side of the outer region 63, and a main body portion 130C between the inner end portion 130A and the outer end portion 130B. The inner end portion 130A defines a region in which the second functional device 60 (that is, the device region 62) is formed in a plan view. The inner end portion 130A may be formed integrally with an insulating film (not shown) formed on the first main surface 42 of the semiconductor chip 41.

The outer end portion 130B is exposed from the chip sidewalls 44A to 44D of the semiconductor chip 41 and is connected to the chip sidewalls 44A to 44D of the semiconductor chip 41. More specifically, the outer end portion 130B is formed flush with the chip sidewalls 44A to 44D of the semiconductor chip 41. The outer end portion 130B forms a ground surface flush with the chip sidewalls 44A to 44D of the semiconductor chip 41 and the insulating sidewalls 53A to 53D of the insulating layer 51 therebetween. Of course, in another embodiment, the outer end portion 130B may be formed in the first main surface 42 at an interval from the chip sidewalls 44A to 44D.

The main body portion 130C has a flat surface extending substantially parallel to the first main surface 42 of the semiconductor chip 41. The main body portion 130C has the connection portion 132 to which the lower end portion (the seal via conductor 65) of the seal conductor 61 is connected. The connection portion 132 is formed in a portion of the main body portion 130C at an interval from the inner end portion 130A and the outer end portion 130B. The isolation structure 130 may have various forms other than the field insulating film 131.

Referring to FIG. 7, the semiconductor device 5 further includes an inorganic insulating layer 140 formed on the insulating main surface 52 of the insulating layer 51 so as to cover the seal conductor 61. The inorganic insulating layer 140 may be called a passivation layer. The inorganic insulating layer 140 protects the insulating layer 51 and the semiconductor chip 41 from above the insulating main surface 52.

In the present embodiment, the inorganic insulating layer 140 has a laminated structure including a first inorganic insulating layer 141 and a second inorganic insulating layer 142. The first inorganic insulating layer 141 may contain silicon oxide. The first inorganic insulating layer 141 preferably contains undoped silicate glass (USG) which is impurity-free silicon oxide. A thickness of the first inorganic insulating layer 141 may be 50 nm or more and 5,000 nm or less. The second inorganic insulating layer 142 may contain silicon nitride. A thickness of the second inorganic insulating layer 142 may be 500 nm or more and 5,000 nm or less. By increasing a total thickness of the inorganic insulating layer 140, the dielectric withstand voltage on the high-potential coil 23 can be increased.

When the first inorganic insulating layer 141 is made of USG and the second inorganic insulating layer 142 is made of silicon nitride, a dielectric breakdown voltage (V/cm) of USG exceeds a dielectric breakdown voltage (V/cm) of silicon nitride. Therefore, when the inorganic insulating layer 140 is thickened, it is preferable to form the first inorganic insulating layer 141 to be thicker than the second inorganic insulating layer 142.

The first inorganic insulating layer 141 may contain at least one selected from the group of a boron doped phosphor silicate glass (BPSG) and a phosphorus silicate glass (PSG) as an example of silicon oxide. However, in this case, since impurities (boron or phosphorus) are contained in silicon oxide, it is particularly preferable to form the first inorganic insulating layer 141 made of USG in order to increase the dielectric withstand voltage on the high-potential coil 23. Of course, the inorganic insulating layer 140 may have a single layer structure including either the first inorganic insulating layer 141 or the second inorganic insulating layer 142.

The inorganic insulating layer 140 covers the entire region of the seal conductor 61 and has a plurality of low-potential pad openings 143 and a plurality of high-potential pad openings 144 formed outside the seal conductor 61. The plurality of low-potential pad openings 143 expose the plurality of low-potential terminals 11, respectively. The plurality of high-potential pad openings 144 expose the plurality of high-potential terminals 12, respectively. The inorganic insulating layer 140 may have an overlap portion that extends over the peripheral edge portion of the low-potential terminal 11. The inorganic insulating layer 140 may have an overlap portion that extends over the peripheral edge portion of the high-potential terminal 12.

The semiconductor device 5 further includes an organic insulating layer 145 formed on the inorganic insulating layer 140. The organic insulating layer 145 may contain a photosensitive resin. The organic insulating layer 145 may contain at least one selected from the group of polyimide, polyamide, and polybenzoxazole. In the present embodiment, the organic insulating layer 145 contains polyimide. A thickness of the organic insulating layer 145 may be 1 μm or more and 50 μm or less.

A thickness of the organic insulating layer 145 preferably exceeds the total thickness of the inorganic insulating layer 140. Further, a total thickness of the inorganic insulating layer 140 and the organic insulating layer 145 is preferably equal to or larger than the distance D2 between the low-potential coil 22 and the high-potential coil 23. In this case, the total thickness of the inorganic insulating layer 140 is preferably 2 μm or more and 10 μm or less. Further, the thickness of the organic insulating layer 145 is preferably 5 μm or more and 50 μm or less. According to these structures, it is possible to suppress the thickening of the inorganic insulating layer 140 and the organic insulating layer 145, and at the same time, it is possible to appropriately increase the dielectric withstand voltage on the high-potential coil 23 by a laminated film of the inorganic insulating layer 140 and the organic insulating layer 145.

The organic insulating layer 145 includes a first portion 146 covering a low-potential side region and a second portion 147 covering a high-potential side region. The first portion 146 covers the seal conductor 61 with the inorganic insulating layer 140 interposed therebetween. The first portion 146 has a plurality of low-potential terminal openings 148 exposing the plurality of low-potential terminals 11 (the low-potential pad openings 143), respectively, in a region outside the seal conductor 61. The first portion 146 may have an overlap portion that extends over the peripheral edge (overlap portion) of the low-potential pad opening 143.

The second portion 147 is formed at an interval from the first portion 146 and exposes the inorganic insulating layer 140 between the first portion 146 and the second portion 147. The second portion 147 has a plurality of high-potential terminal openings 149 exposing the plurality of high-potential terminals 12 (the high-potential pad openings 144), respectively. The second portion 147 may have an overlap portion that extends over the peripheral edge (overlap portion) of the high-potential pad opening 144.

The second portion 147 collectively covers the transformers 21A to 21D and the dummy pattern 85. Specifically, the second portion 147 collectively covers the plurality of high-potential coils 23, the plurality of high-potential terminals 12, a first high-potential dummy pattern 87, a second high-potential dummy pattern 88, and a floating dummy pattern 121.

The embodiment of the present disclosure may be implemented in other forms. In the above-described embodiments, an example in which the first functional device 45 and the second functional device 60 are formed has been described. However, a form having only the second functional device 60 without having the first functional device 45 may be adopted. In this case, the dummy pattern 85 may be removed. According to this structure, the second functional device 60 can achieve the same effects as those described in the first embodiment (excluding the effects related to the dummy pattern 85).

That is, when a voltage is applied to the second functional device 60 via the low-potential terminal 11 and the high-potential terminal 12, unwanted conduction between the high-potential terminal 12 and the seal conductor 61 can be suppressed. Further, when a voltage is applied to the second functional device 60 via the low-potential terminal 11 and the high-potential terminal 12, unwanted conduction between the low-potential terminal 11 and the seal conductor 61 can be suppressed.

Further, in the above-described embodiments, an example in which the second functional device 60 is formed has been described. However, the second functional device 60 is not necessarily required and may be removed.

Further, in the above-described embodiments, an example in which the dummy pattern 85 is formed has been described. However, the dummy pattern 85 is not necessarily required and may be removed.

Further, in the above-described embodiments, an example in which the first functional device 45 is of a multi-channel type including the plurality of transformers 21 has been described. However, a single-channel first functional device 45 including a single transformer 21 may be employed.

### Transformer Arrangement

FIG. 9 is a plan view (top view) schematically showing an example of transformer arrangement in a two-channel transformer chip 300 (corresponding to the above-described semiconductor device 5). The transformer chip 300 in this figure includes a first transformer 301, a second transformer 302, a third transformer 303, a fourth transformer 304, a first guard ring 305, a second guard ring 306, pads a1 to a8, pads b1 to b8, pads c1 to c4, and pads d1 to d4.

In the transformer chip 300, the pads a1 and b1 are connected to one end of a secondary side coil L1s forming the first transformer 301, and the pads c1 and d1 are connected to the other end of the secondary side coil L1s. The pads a2 and b2 are connected to one end of a secondary side coil L2s forming the second transformer 302, and the pads c1 and d1 are connected to the other end of the secondary side coil L2s.

Further, the pads a3 and b3 are connected to one end of a secondary side coil L3s forming the third transformer 303, and the pads c2 and d2 are connected to the other end of the secondary side coil L3s. The pads a4 and b4 are connected to one end of a secondary side coil L4s forming the fourth transformer 304, and the pads c2 and d2 are connected to the other end of the secondary side coil L4s.

A primary side coil forming the first transformer 301, a primary side coil forming the second transformer 302, a primary side coil forming the third transformer 303, and a primary side coil forming the fourth transformer 304 are not shown in this figure. However, the primary side coils basically have the same configuration as the secondary side coils L1s to L4s, respectively, and are arranged directly below the secondary side coils L1s to L4s, respectively, so as to face the secondary side coils L1s to L4s, respectively.

That is, the pads a5 and b5 are connected to one end of the primary side coil forming the first transformer 301, and the pads c3 and d3 are connected to the other end of the primary side coil. The pads a6 and b6 are connected to one end of the primary side coil forming the second transformer 302, and the pads c3 and d3 are connected to the other end of the primary side coil.

Further, the pads a7 and b7 are connected to one end of the primary side coil forming the third transformer 303, and the pads c4 and d4 are connected to the other end of the primary side coil. The pads a8 and b8 are connected to one end of the primary side coil forming the fourth transformer 304, and the pads c4 and d4 are connected to the other end of the primary side coil.

However, the pads a5 to a8, the pads b5 to b8, the pads c3 and c4, and the pads d3 and d4 are led out from the inside of the transformer chip 300 to the surface thereof through vias (not shown).

Among the plurality of pads, the pads a1 to a8 correspond to first current supply pads, respectively, and the pads b1 to b8 correspond to first voltage measurement pads, respectively. Further, the pads c1 to c4 correspond to second current supply pads, respectively, and the pads d1 to d4 correspond to second voltage measurement pads, respectively.

Therefore, with the transformer chip 300 of this configuration example, a series resistance component of each coil can be accurately measured during a defective product inspection. Therefore, in addition to rejecting defective products in which each coil is disconnected, it is possible to appropriately reject defective products in which the resistance value of each coil is abnormal (for example, a short circuit between coils), and consequently, it is possible to prevent release of defective products to the market in advance.

For the transformer chip 300 that has passed the defective product inspection, the plurality of pads may be used for connection with a primary side chip and a secondary side chip (for example, the controller chip 210 and the driver chip 220 described above).

Specifically, the pads a1 and b1, the pads a2 and b2, the pads a3 and b3, and the pads a4 and b4 may be connected to a signal input end or a signal output end of the secondary side chip. Further, the pads c1 and d1 and the pads c2 and d2 may be connected to a common voltage application end (GND2) of the secondary side chip.

On the other hand, the pads a5 and b5, the pads a6 and b6, the pads a7 and b7, and the pads a8 and b8 may be connected to a signal input end or a signal output end of the primary side chip. Further, the pads c3 and d3 and the pads c4 and d4 may be connected to a common voltage application end (GND1) of the primary side chip.

Here, as shown in FIG. 9, the first to fourth transformers 301 to 304 are coupled and arranged for the respective signal transmission directions. Referring to this figure, for example, the first transformer 301 and the second transformer 302 configured to transmit signals from the primary side chip to the secondary side chip are paired as a first pair by the first guard ring 305. Further, for example, the third transformer 303 and the fourth transformer 304 configured to transmit signals from the secondary side chip to the primary side chip are paired as a second pair by the second guard ring 306.

The reason for such coupling is that when the primary side coil and the secondary side coil forming each of the first to fourth transformers 301 to 304 are laminated in the vertical direction of the substrate of the transformer chip 300, a withstand voltage between the primary side coil and the secondary side coil is ensured. However, the first guard ring 305 and the second guard ring 306 are not necessarily essential components.

Further, the first guard ring 305 and the second guard ring 306 may be connected to a low-impedance wiring such as a ground end via pads e1 and e2, respectively.

Further, in the transformer chip 300, the pads c1 and d1 are shared between the secondary side coil L1s and the secondary side coil L2s. Further, the pads c2 and d2 are shared between the secondary side coil L3s and the secondary side coil L4s. Further, the pads c3 and d3 are shared between the primary side coil L1p and the primary side coil L2p. Further, the pads c4 and d4 are shared with the corresponding respective primary side coils. With such a configuration, the number of pads can be reduced, and downsizing of the transformer chip 300 can be achieved.

Further, as shown in FIG. 9, it is desirable that the primary side coil and the secondary side coil forming each of the first to fourth transformers 301 to 304 are wound in a rectangular shape (or a track shape with rounded corners) in a plan view of the transformer chip 300. With such a configuration, an area of a portion where the primary side coil and the secondary side coil overlap with each other becomes large, making it possible to improve the transmission efficiency of the transformer.

Of course, the transformer arrangement in this figure is only an example, and the number, shapes, and arrangements of coils and arrangements of pads are arbitrary. Further, the chip structure, the transformer arrangement, and the like described above may be applied to general semiconductor devices in which coils are integrated on a semiconductor chip.

### Insulation Switch (First Embodiment)

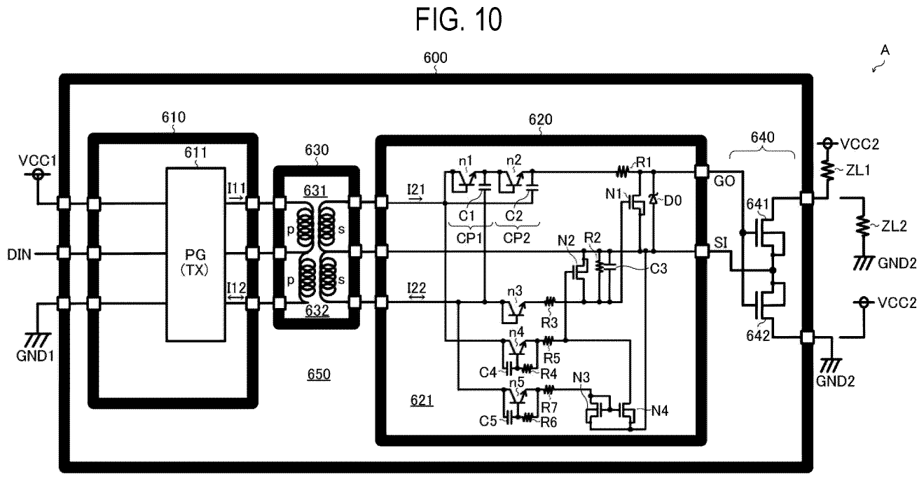

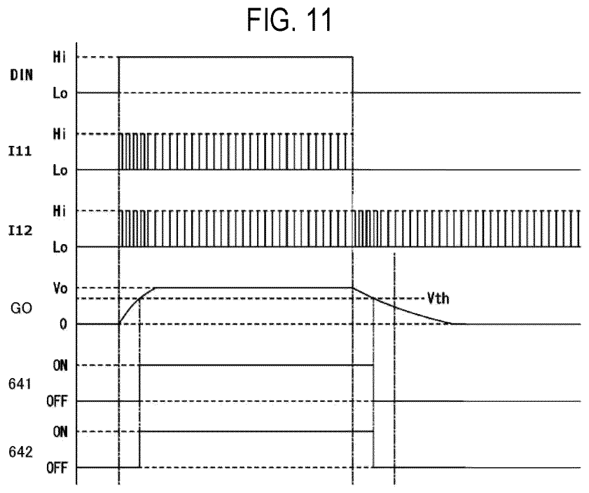

FIG. 10 shows a first embodiment of an insulation switch 600. The insulation switch 600 of the present embodiment can be mounted in an electronic apparatus A together with a load ZL1 or ZL2. The electronic apparatus A may be, for example, an in-vehicle apparatus.

Referring to this figure, the insulation switch 600 includes a first chip 610, a second chip 620, a third chip 630, and a switch circuit 640. The first chip 610, the second chip 620, and the third chip 630 may be sealed in a single package.

The first chip 610 includes, for example, a pulse generation circuit 611 integrated therein. The pulse generation circuit 611 corresponds to a transmission circuit configured to generate a first transmission signal and a second transmission signal in response to an input signal. Referring to this diagram, the pulse generation circuit 611 generates pulse signals I11 and I12 in response to a logic level of an externally input pulse signal DIN. For example, the pulse generation circuit 611 generates the pulse signal I11 when the input pulse signal DIN is at a high level. In addition, the pulse generation circuit 611 generates the pulse signal I12 when the input pulse signal DIN is at a low level. The first chip 610 can be understood as a transmission chip.

The second chip 620 includes, for example, a reception circuit 621 integrated therein. The reception circuit 621 generates an output pulse signal GO in response to induced currents I21 and I22 output from the third chip 630. The second chip 620 can be understood as a reception chip. The induced currents I21 and I22 can be understood as a first reception signal and a second reception signal, respectively.

Referring to this diagram, the reception circuit 621 includes transistors n1 to n5, transistors N1 to N4, capacitors C1 to C5, resistors R1 to R7, and a Zener diode D0. The transistors n1 to n5 may be, for example, of an npn type. The transistors N1 to N4 may be, for example, of an N-channel type.

A base and a collector of the transistor n1 are connected to an application end of the induced current I21, i.e., a first end of a secondary side coil 631s to be described below. An emitter of the transistor n1 and a base and a collector of the transistor n2 are connected to a first end of the capacitor C1. An emitter of the transistor n2 and a first end of the resistor R1 are connected to a first end of the capacitor C2. A second end of the capacitor C1 is connected to the application end of the induced current I22, i.e., a first end of a secondary side coil 632s to be described below. A second end of the capacitor C2 is connected to the application end of the induced current I21.

In this way, the transistors n1 and n2 are diode-connected between the application end of the induced current I21 and an application end of the output pulse signal GO, with a direction of the induced current I21 being a forward direction. In addition, the capacitor C1 is connected between the emitter of the transistor n1 and an application end of the induced current I22. On the other hand, the capacitor C2 is connected between the emitter of the transistor n2 and the application end of the induced current I21.

In this configuration, the transistor n1 and the capacitor C1 form a first-stage boost circuit CP1. In addition, the transistor n2 and the capacitor C2 form a second-stage boost circuit CP2. In other words, the reception circuit 621 includes multiple stages (two stages in this figure) of boost circuits CP1 and CP2 connected in series between the application end of the induced current I21 and the application end of the output pulse signal GO. The boost circuits CP1 and CP2 not only function as rectifying/smoothing circuits, but also operate to raise the high level of the output pulse signal GO.

A second end of the resistor R1, a drain of the transistor N1, and a cathode of the Zener diode D0 are connected to the application end of the output pulse signal GO (=a control end of the switch circuit 640). A source and a back gate of the transistor N1 and the anode of the Zener diode D0 are connected to an application end of a reference signal SI. The application end of the reference signal SI can be understood as a reference potential end.

A base and a collector of the transistor n3 are connected to the application end of the induced current I22. An emitter of the transistor n3 is connected to a first end of the resistor R3. A second end of the resistor R3 is connected to a gate of the transistor N1.

A first end of a resistor R2, a first end of the capacitor C3, and a source and a back gate of the transistor N2 are connected to the application end of the reference signal SI. A second end of each of the resistor R2 and the capacitor C3 and a drain of the transistor N2 are connected to the gate of the transistor N1.

A collector of the transistor n4 and a first end of the capacitor C4 are connected to the application end of the induced current I21. A base of the transistor n4 is connected to a second end of the capacitor C4 and a first end of the resistor R4. An emitter of the transistor n4 and a second end of the resistor R4 are connected to the first end l of the resistor R5. The second end of the resistor R5 is connected to a gate of the transistor N2.

A collector of the transistor n5 and a first end of the capacitor C5 are connected to the application end of the induced current I22. A base of the transistor n5 is connected to a second end of the capacitor C5 and a first end of the resistor R6. An emitter of the transistor n5 and a second end of the resistor R6 are connected to a first end of the resistor R7. A second end of the resistor R7 is connected to a drain of the transistor N3.

A gate of each of the transistors N3 and N4 is connected to the drain of the transistor N3. A drain of the transistor N4 is connected to the gate of the transistor N2. The source of each of the transistors N3 and N4 is connected to the application end of the reference signal SI. The transistors N3 and N4 form a current mirror configured to replicate a drain current of the transistor N3 as a drain current of the transistor N4.

The third chip 630 corresponds to an insulation circuit configured to electrically insulate the first chip 610 and the second chip 620 from each other while transmitting the pulse signals I11 and I12 of the first chip 610 as pulse signals (the induced currents I21 and I22) of the second chip 620.

Referring to this figure, the third chip 630 includes insulating elements 631 and 632 integrated therein. The insulating element 631 may be a transformer including a primary side coil 631p to which the pulse signal I11 is applied and a secondary side coil 631s that is electromagnetically coupled to the primary side coil 631p and configured to induce the induced current I21. The insulating element 632 may be a transformer including a primary side coil 632p to which the pulse signal I12 is applied and a secondary side coil 632s that is electromagnetically coupled to the primary side coil 632p and configured to induce the induced current I22. A second end of each of the secondary side coils 631s and 632s is connected to the application end of the reference signal SI.

The primary side coils 631p and 632p are connected in series. A second end of each of the primary side coils 631p and 632p, i.e., a connection tap between the two coils, is connected to an application end of a ground voltage GND1. In addition, the secondary side coils 631s and 632s are connected in series. A second end of each of the secondary side coils 631s and 632s, i.e., a connection tap between the two coils, is connected to the application end of the reference signal SI.

In particular, the primary side coils 631p and 632p have winding directions opposite to each other. Therefore, in the insulating element 631, for example, when the pulse signal I11 flows from the first end to the second end of the primary side coil 631p (from top to bottom in this figure), the induced current I21 flows from the second end to the first end of the secondary side coil 631s (from bottom to top in this figure). In contrast, in the isolation element 632, for example, when the pulse signal I12 flows from the first end to the second end of the primary side coil 632p (from bottom to top in this figure), the induced current I22 flows from the first end to the second end of the secondary side coil 632s (from bottom to top in this figure). Therefore, electromagnetic noise emitted from the third chip 630 can be reduced.

The first chip 610, the second chip 620, and the third chip 630 form a signal transmitter 650 configured to transmit pulse signals from a primary circuit system (VCC1-GND1 system) to a secondary circuit system (VCC2-GND2 system) while insulating the primary circuit system and the secondary circuit system from each other. The signal transmitter 650 may be integrated into a semiconductor integrated circuit device (a so-called isolated gate driver IC) and provided to the market.

The switch circuit 640 is driven in response to the output pulse signal GO. The switch circuit 640 includes switch elements 641 and 642. The switch elements 641 and 642 may be, for example, of an N-channel type. A source and a back gate of each of the switch elements 641 and 642 are connected to the application end of the reference signal SI. A gate of each of the switch elements 641 and 642 is connected to the application end of the output pulse signal GO.

In a first connection mode, a drain of the switch element 641 may be connected to the application terminal of the power supply voltage VCC2 via the load ZL1, and a drain of the switch element 642 may be connected to the application end of the ground voltage GND2. In this case, the switch circuit 640 functions as a lower switch.

In a second connection mode, the drain of the switch element 641 may be connected to the application end of the ground voltage GND2 via the load ZL2, and the drain of the switch element 642 may be connected to the application end of the power supply voltage VCC2. In this case, switch circuit 640 functions as an upper switch.

FIG. 11 shows a signal transmission operation in the first embodiment. From top to bottom, this figure depicts the input pulse signal DIN, the pulse signals I11 and I12, the output pulse signal GO, and on/off state of each of the switch elements 641 and 642.

As shown in this figure, when the input pulse signal DIN switches from a low level to a high level, pulse driving of each of the pulse signals I11 and I12 begins. Therefore, the induced currents I21 and I22 are generated in the second chip 620. This causes each of the switch elements 641 and 642 to switch on.

On the other hand, when the input pulse signal DIN switches from the high level to the low level, the pulse driving of the pulse signal I11 stops, while the pulse driving of the pulse signal I12 continues. Therefore, the induced current I21 stops flowing, while the induced current I22 continues to flow. This causes each of the switch elements 641 and 642 to enter an off state.

### Insulation Switch (Second Embodiment)

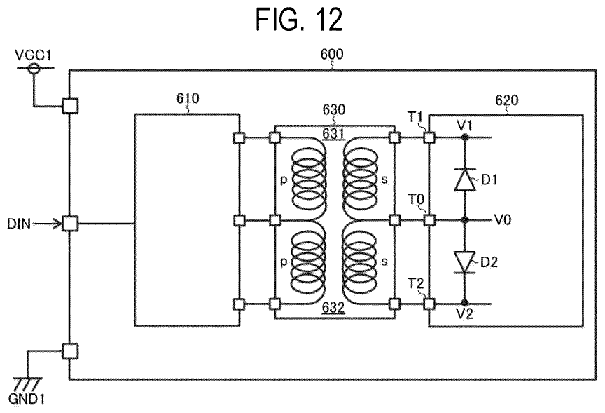

FIG. 12 shows a second embodiment of the insulation switch 600. The insulation switch 600 of this embodiment is based on the first embodiment (FIG. 10) described above, but diodes D1 and D2 are integrated into the second chip 620.

A cathode of the diode D1 is connected to a pad T1 of the second chip 620. A node voltage V1 is applied to the pad T1. The node voltage V1 can be understood as a first reception signal transmitted via a transformer 631. A cathode of the diode D2 is connected to a pad T2 of the second chip 620. A node voltage V2 is applied to the pad T2. The node voltage V2 can be understood as a second reception signal transmitted via a transformer 632.

An anode of each of the diodes D1 and D2 is connected to a pad T0 of the second chip 620. A node voltage V0 is applied to the pad T0. The node voltage V0 can be understood as a reference voltage. In other words, the pad T0 can be understood as a reference potential end.

The diode D1 can function as an electrostatic protection element for dissipating positive surges that may be applied between the pads T1 and T0. The diode D2 can function as an electrostatic protection element configured to dissipate positive surges that may be applied between the pads T2 and T0.

### Considerations on Electrostatic Breakdown Withstand Voltage and Signal Attenuation

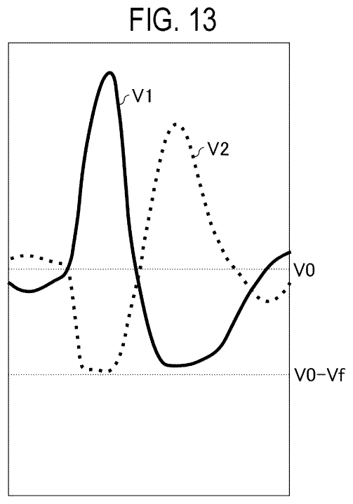

FIG. 13 shows an example of a reception signal in the second embodiment. A solid line indicates the node voltage V1. A dashed line indicates the node voltage V2. As shown in this figure, the node voltages V1 and V2, which swing positive and negative around the reference voltage V0, can be applied to the pads T1 and T2, respectively.

However, in a case where the node voltage V1 falls below the reference voltage V0, a forward current flows through the diode D1. Therefore, the node voltage V1 is clamped at a negative voltage (=V0−Vf) that is lower than the reference voltage V0 by a forward drop voltage Vf. The same applies to the node voltage V2. In this way, when the node voltages V1 and V2 are clamped on the negative side, the reception signal is attenuated accordingly. This may result in deterioration in the communication efficiency of the signal transmitter 650, and in turn, in the drive efficiency of the isolation switch 600, which may lead to a decrease in the output pulse signal GO.

Further, as a parasitic capacitance between the anode and the cathode of each of the diodes D1 and D2 becomes larger, a waveform of each of the node voltages V1 and V2 becomes duller. This waveform dullness may also lead to attenuation of the reception signal, and in turn, to a deterioration in the communication efficiency or drive efficiency.

In light of the above considerations, a third embodiment is proposed that can suppress the reception signal attenuation without compromising an electrostatic breakdown withstand voltage.

### Insulation Switch (third Embodiment)

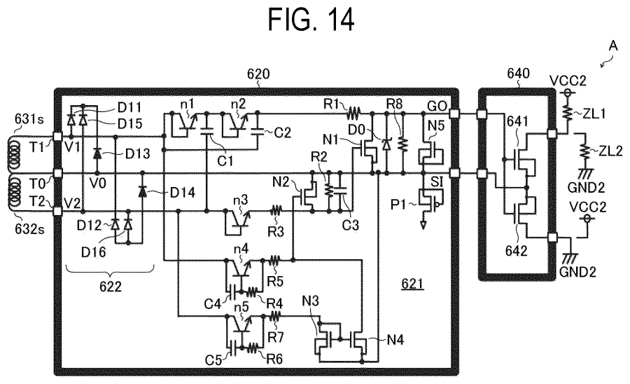

FIG. 14 shows a third embodiment of the insulation switch 600. For ease of illustration, this figure depicts only some components, centering on the second chip 620. In this embodiment of the insulation switch 600, the second chip 620 includes an electrostatic protection circuit 622 in addition to the above-described reception circuit 621.

The reception circuit 621 receives the node voltages V1 and V2 from the pads T1 and T2, respectively, and generates the output pulse signal GO. Referring to this figure, the reception circuit 621 includes a resistor R8 and transistors N5 and P1 in addition to the components of the first embodiment (FIG. 10). The transistor N5 may be, for example, of an N-channel type. The transistor P1 may be, for example, of a P-channel type.

A first end of the resistor R8 and a drain of the transistor N5 are connected to the application end of the output pulse signal GO. A second terminal of the resistor R8, a source and a gate of the transistor N5, and a source and a gate of the transistor P1 are connected to the application end of the reference signal SI. A drain of the transistor P1 is connected to a constant potential node.

The electrostatic protection circuit 622 includes diodes D11 to D16 as electrostatic protection elements. An anode of the diode D11 and a cathode of the diode D12 are connected to the pad T1. An anode of the diode D15 and a cathode of the diode D16 are connected to the pad T2. A cathode of the diode D13 is connected to a cathode of each of the diodes D11 and D15. An anode of the diode D14 is connected to an anode of each of the diodes D12 and D16. An anode of the diode D13 and a cathode of the diode D14 are connected to the pad T0.

The diodes D11 to D16 may each be diode-connected transistors, or parasitic diodes associated with transistors. A basic operation of the electrostatic protection circuit 622 will be described in detail below with reference to the drawings.

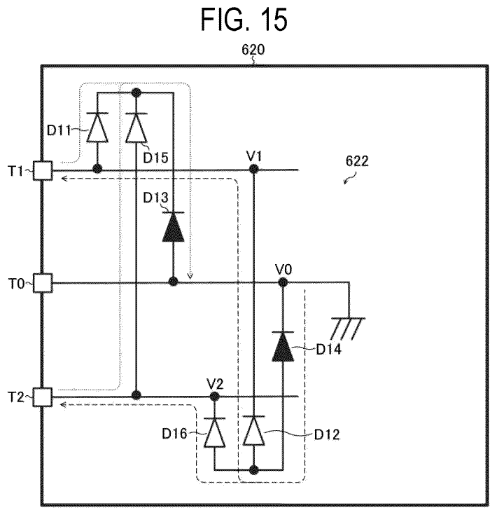

FIG. 15 shows an example of a surge path in the electrostatic protection circuit 622. When a positive surge is applied to the pad T1, charges are discharged from the pad T1 to the pad T0 via the diode D11 in a forward bias state and the diode D13 in a breakdown state. In addition, when a positive surge is applied to the pad T2, charges are discharged from the pad T2 to the pad T0 via the diode D15 in a forward bias state and the diode D13 in the breakdown state. By forming such a current path, the reception circuits 621 connected to each of the pads T1 and T2 can be protected from the positive surge.

On the other hand, when a negative surge is applied to the pad T1, charges are discharged from the pad T0 to the pad T1 via the diode D14 in a breakdown state and the diode D12 in a forward bias state. In addition, when a negative surge is applied to the pad T2, charges are discharged from the pad T0 to the pad T2 via the diode D14 in the breakdown state and the diode D16 in a forward bias state. By forming such a current path, the reception circuits 621 connected to each of the pads T1 and T2 can be protected from the negative surge.

The breakdown state described above refers to a state in which a voltage above a threshold is applied to the diodes D11 to D16 (for example, the diodes D13 and D14 in the above operation) in a reverse bias state, thereby allowing a reverse current to flow.

In this way, the current paths configured to discharge the positive or negative surge that may be applied to the pads T1 and T2, respectively, are both connected to the pad T0, i.e., a single reference potential end, via the diodes D13 and D14 in the breakdown state. When the node voltage V1 applied to the pad T1 swings negative (<V0), the diodes D11 and D14 become reverse-biased. On the other hand, when the node voltage V2 applied to the pad T2 swings negative (<V0), the diodes D14 and D15 become reverse-biased. Therefore, no current paths are formed from the pad T0 to the pads T1 and T2 unless the diodes D11, D14, and D15 reach a breakdown state. Therefore, unlike the above-described second embodiment (FIG. 12), the node voltages V1 and V2 are no longer clamped on the negative side, thereby reducing attenuation of the reception signal. As a result, the communication efficiency of the signal transmitter 650 and in turn the drive efficiency of the insulation switch 600 are improved, and the decrease in the output pulse signal GO can be eliminated.

Here, it is desirable that the parasitic capacitance between the anode and the cathode of each of the diodes D11, D12, D15, and D16, which are directly connected to the pads T1 and T2, respectively, be as small as possible. With this configuration, the waveform of each of the node voltages V1 and V2 is less likely to become dull. Therefore, the attenuation of the reception signal is suppressed, which is expected to improve the communication efficiency and drive efficiency.

Further, in order to efficiently dissipate the surges, which may be applied to the pads T1 and T2, to the pad T0, it is desirable that the current capacity of each of the diodes D11, D12, D15, and D16 in a forward bias state be as large as possible. However, the current capacity in a reverse bias state may be small.

On the other hand, for the diodes D13 and D14, which may enter a breakdown state when a surge is applied, it is desirable that their current capacity in a reverse bias state be as large as possible. It is also acceptable for their current capacity in a forward bias state to be large. The diodes D13 and D14 are not directly connected to either the pad T1 or T2. Therefore, the parasitic capacitance associated with each diode between its anode and cathode may be large. It is also desirable for the diodes D13 and D14 to be high-withstand voltage elements that will not be destroyed even when a surge is applied.

In light of the above, and when focusing on the parasitic capacitance, the parasitic capacitance associated between the anode and the cathode of each of the diodes D11, D12, D15, and D16, shown in white, may be smaller than the parasitic capacitance associated between the anode and the cathode of each of the diodes D13 and D14, shown in black.

Further, when focusing on the current capacity in the reverse bias state, the current capacity in the reverse bias state of each of the diodes D13 and D14, shown in black, may be greater than the current capacity in the reverse bias state of each of the diodes D11, D12, D15, and D16, shown in white.

The electrostatic protection circuit 622 of the present embodiment makes it possible to suppress attenuation of the reception signal without compromising an electrostatic breakdown withstand voltage.

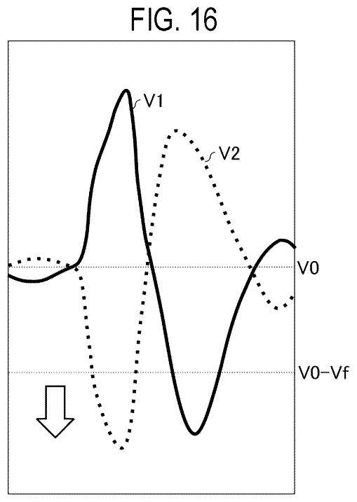

FIG. 16 is a diagram showing an example of a reception signal in the third embodiment. As with FIG. 13 described above, a solid line represents the node voltage V1. A dashed line represents the node voltage V2. As shown in this figure, the node voltages V1 and V2, which swing positive and negative around the reference voltage V0, can be applied to the pads T1 and T2, respectively.

In the electrostatic protection circuit 622 of the present embodiment, when the node voltages V1 and V2 swing negative (<V0), the diodes D14 and D15 enter a reverse bias state, thereby blocking a current path from the pad T0 to the pads T1 and T2. Therefore, the node voltages V1 and V2 are no longer clamped to the negative side, thereby reducing attenuation of the reception signal. As a result, the communication efficiency of the signal transmitter 650 and in turn the drive efficiency of the insulation switch 600 are improved, and the decrease in the output pulse signal GO can be eliminated.

### Supplementary Notes

According to the present disclosure, it is possible to reduce attenuation of the reception signal and improve the communication efficiency without compromising an electrostatic breakdown withstand voltage. The following supplementary notes are added to the present disclosure.

### Supplementary Note 1

An electrostatic protection circuit (622) including:
a first protection element (D11) configured with an anode connected to a first pad (T1);
a second protection element (D12) configured with a cathode connected to the first pad (T1);
a third protection element (D13) configured with a cathode connected to a cathode of the first protection element (D11) and an anode connected to a reference potential terminal (T0); and
a fourth protection element (D14) configured with an anode connected to an anode of the second protection element (D12) and a cathode connected to the reference potential terminal (T0).

### Supplementary Note 2

The electrostatic protection circuit (622) of Supplementary Note 1, further including:
a fifth protection element (D15) configured with an anode connected to a second pad (T2) and a cathode connected to the cathode of the third protection element (D13); and
a sixth protection element (D16) configured with a cathode connected to the second pad (T2) and an anode connected to the anode of the fourth protection element (D14).

### Supplementary Note 3

The electrostatic protection circuit (622) of Supplementary Note 1 or 2, wherein a parasitic capacitance associated between the anode and the cathode of each of the first protection element (D11) and the second protection element (D12) is smaller than a parasitic capacitance associated between the anode and the cathode of each of the third protection element (D13) and the fourth protection element (D14).

### Supplementary Note 4

The electrostatic protection circuit (622) of Supplementary Note 2, wherein a parasitic capacitance associated between the anode and the cathode of each of the fifth protection element (D15) and the sixth protection element (D16) is smaller than a parasitic capacitance associated between the anode and the cathode of each of the third protection element (D13) and the fourth protection element (D14).

### Supplementary Note 5

The electrostatic protection circuit (622) of any one of Supplementary Notes 1 to 4, wherein a current capacity in a reverse bias state of each of the third protection element (D13) and the fourth protection element (D14) is greater than a current capacity in a reverse bias state of each of the first protection element (D11) and the second protection element (D12).

### Supplementary Note 6

The electrostatic protection circuit (622) of Supplementary Note 2 or 4, wherein a current capacity in a reverse bias state of each of the third protection element (D13) and the fourth protection element (D14) is greater than a current capacity in a reverse bias state of each of the fifth protection element (D15) and the sixth protection element (D16).

### Supplementary Note 7

The electrostatic protection circuit (622) of any one of Supplementary Notes 1 to 6, wherein each of the first protection element (D11), the second protection element (D12), the third protection element (D13), and the fourth protection element (D14) is a diode, a diode-connected transistor, or a parasitic diode associated with a transistor.

### Supplementary Note 8

The electrostatic protection circuit (622) of any one of Supplementary Notes 2, 4, and 6, wherein each of the fifth protection element (D15) and the sixth protection element (D16) is a diode, a diode-connected transistor, or a parasitic diode associated with a transistor.

### Supplementary Note 9

A reception chip (620) including:
a first pad (T1);
a reception circuit (621) configured to receive a signal from the first pad (T1); and
the electrostatic protection circuit (622) of any one of Supplementary Notes 1 to 8.

### Supplementary Note 10

A reception chip (620) including:
a first pad (T1);
a second pad (T2);
a reception circuit (621) configured to receive a signal from each of the first pad (T1) and the second pad (T2); and
the electrostatic protection circuit (622) of any one of Supplementary Notes 2, 4, 6, and 8.

### Supplementary Note 11

A signal transmitter (650) including:
a transmission chip (610) configured to transmit a signal;
the reception chip (620) of Supplementary Note 9 or 10; and
an insulation circuit (630) configured to transmit the signal between the transmission chip (610) and the reception chip (620) while insulating the transmission chip (610) and the reception chip (620) from each other.

### Supplementary Note 12

An electronic apparatus (A) including:
the signal transmitter (650) of Supplementary Note 11.

### Others

In addition to the above-described embodiments, the various technical features disclosed in the present disclosure may be modified in various ways without departing from the spirit of the technical creation. In other words, the above-described embodiments should be considered illustrative and not restrictive in all respects. Furthermore, the technical scope of the present disclosure is defined by the claims, and should be understood to include all modifications that fall within the meaning and scope of equivalents of the claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An electrostatic protection circuit comprising:
a first protection element configured with an anode connected to a first pad;
a second protection element configured with a cathode connected to the first pad;
a third protection element configured with a cathode connected to a cathode of the first protection element and an anode connected to a reference potential terminal; and
a fourth protection element configured with an anode connected to an anode of the second protection element and a cathode connected to the reference potential terminal.

2. The electrostatic protection circuit of claim 1, further comprising:
a fifth protection element configured with an anode connected to a second pad and a cathode connected to the cathode of the third protection element; and
a sixth protection element configured with a cathode connected to the second pad and an anode connected to the anode of the fourth protection element.

3. The electrostatic protection circuit of claim 1, wherein a parasitic capacitance associated between the anode and the cathode of each of the first protection element and the second protection element is smaller than a parasitic capacitance associated between the anode and the cathode of each of the third protection element and the fourth protection element.

4. The electrostatic protection circuit of claim 2, wherein a parasitic capacitance associated between the anode and the cathode of each of the fifth protection element and the sixth protection element is smaller than a parasitic capacitance associated between the anode and the cathode of each of the third protection element and the fourth protection element.

5. The electrostatic protection circuit of claim 1, wherein a current capacity in a reverse bias state of each of the third protection element and the fourth protection element is greater than a current capacity in a reverse bias state of each of the first protection element and the second protection element.

6. The electrostatic protection circuit of claim 2, wherein a current capacity in a reverse bias state of each of the third protection element and the fourth protection element is greater than a current capacity in a reverse bias state of each of the fifth protection element and the sixth protection element.

7. The electrostatic protection circuit of claim 1, wherein each of the first protection element, the second protection element, the third protection element, and the fourth protection element is a diode, a diode-connected transistor, or a parasitic diode associated with a transistor.

8. The electrostatic protection circuit of claim 2, wherein each of the fifth protection element and the sixth protection element is a diode, a diode-connected transistor, or a parasitic diode associated with a transistor.

9. A reception chip comprising:
a first pad;
a reception circuit configured to receive a signal from the first pad; and
the electrostatic protection circuit of claim 1.

10. A reception chip comprising:
a first pad;
a second pad;
a reception circuit configured to receive a signal from each of the first pad and the second pad; and
the electrostatic protection circuit of claim 2.

11. A signal transmitter comprising:
a transmission chip configured to transmit a signal;
the reception chip of claim 9; and
an insulation circuit configured to transmit the signal between the transmission chip and the reception chip while insulating the transmission chip and the reception chip from each other.

12. An electronic apparatus comprising:
the signal transmitter of claim 11.
